(19) United States
(12) Patent Application Publication
(10) Pub. No.: US 2026/0291152 A1
(43) Pub. Date: Sep. 24, 2026

(54) CIRCUIT BOARD OF ELECTRICAL CONNECTION DEVICE, AND ELECTRICAL CONNECTION DEVICE

(71) Applicant: GD MIDEA AIR-CONDITIONING EQUIPMENT CO., LTD., Foshan (CN)

(72) Inventors: Liwei NIU, Foshan (CN); Huake WANG, Foshan (CN); Aiguo TAN, Foshan (CN)

(21) Appl. No.: 19/683,225

(22) Filed: May 20, 2026

Related U.S. Application Data
(63) Continuation of application No. PCT/CN2024/114248, filed on Aug. 23, 2024.

(30) Foreign Application Priority Data
Nov. 29, 2023 (CN) 202311621811.9
May 13, 2024 (CN) 202410590986.6
May 13, 2024 (CN) 202421037099.8

(51) Int. Cl. H01R 13/713; H01R 13/66; H01R 24/30; H05K 1/16

(52) U.S. Cl. CPC H01R 13/713; H01R 13/6683; H01R 24/30; H05K 1/162; H05K 1/165; H05K 2201/10053

(57) ABSTRACT

A circuit board of an electrical connection device. The electrical connection device includes power cord, detection-protection apparatus, and housing. The detection-protection apparatus includes open-circuit detector, electric leakage detector, driver, tripping mechanism, tester including test switch, and reset button. The tripping mechanism is arranged in the middle area of first surface of the circuit board. Current-carrying conductors are provided on two sides of the tripping mechanism. Second surface of the circuit board has first area located at the edge of the circuit board. The open-circuit detector is arranged in the first area. The first surface has shielding conductor solder point at position corresponding to the first area. The test switch and the reset button are arranged in the middle area of the second surface. The electric leakage detector and the driver are arranged in the areas of the second surface adjacent to the test switch and the reset button.

### CROSS-REFERENCE TO RELATED APPLICATIONS

This application is a continuation of International Application No. PCT/CN2024/114248, filed on Aug. 23, 2024, which claims priority to Chinese Patent Application No. 202311621811.9, filed on Nov. 29, 2023 and entitled “CIRCUIT BOARD OF ELECTRICAL CONNECTION DEVICE, AND ELECTRICAL CONNECTION DEVICE,” Chinese Patent Application No. 202410590986.6, filed on May 13, 2024 and entitled “CIRCUIT BOARD OF ELECTRICAL CONNECTION DEVICE, AND ELECTRIC CONNECTION DEVICE,” and Chinese Patent Application No. 202421037099.8, filed on May 13, 2024 and entitled “CIRCUIT BOARD OF ELECTRICAL CONNECTION DEVICE, AND ELECTRIC CONNECTION DEVICE,” the entire contents of all of which are incorporated herein by reference for all purposes.

### TECHNICAL FIELD

The present disclosure relates to the technical field of circuit boards, and in particular, to a circuit board of an electrical connection device and an electrical connection device.

### BACKGROUND

A leakage circuit detector interrupter (LCDI) is a power supply connection device for electrical appliances that monitors leakage current in a power cord assembly through dedicated leakage current detection conductors. When a specified level of leakage current is detected, the LCDI interrupts the electrical connection to the electrical appliances to ensure safe operation. In recent years, in addition to monitoring leakage current along the power cord, LCDI devices have been required to meet more advanced safety demands—for instance, the capability to detect whether the leakage current detection conductor itself is in an open-circuit condition.

### SUMMARY

The present disclosure aims to at least partially resolve one of technical problems existing in the existing technology. To this end, the present disclosure provides a circuit board of an electrical connection device and an electrical connection device.

In accordance with a first aspect of the present disclosure, an embodiment provides a circuit board of an electrical connection device, where the electrical connection device includes a power cord, a detection-protection apparatus arranged at the circuit board and connected to the power cord, and a housing enclosing the circuit board; and the housing is provided with conductive pins for accessing a power supply; where
the power cord includes a first current-carrying wire, a second current-carrying wire, a first shielding conductor structure wrapping the first current-carrying wire, and a second shielding conductor structure wrapping the second current-carrying wire;
the detection-protection apparatus includes an open-circuit detector, a leakage current detector, a driver, a tripping mechanism, a tester incorporating a test switch, and a reset button;
the circuit board has a first board surface facing the conductive pins and a second board surface facing away from the conductive pins;
the tripping mechanism is arranged in a central region of the first board surface; and the tripping mechanism are provided with current-carrying conductors at two sides for receiving electrical power through a press-contact with the conductive pins;
the second board surface is provided with a first region located at an edge of the circuit board where the open-circuit detector is arranged, and the first board surface is arranged with a shielding conductor solder joint for soldered connection of the first shielding conductor structure and/or the second shielding conductor structure, the shielding conductor solder joint being located corresponding to the first region; and
the test switch and the reset button are arranged in a central region of the second board surface; and the leakage current detector and the driver are arranged in a region of the second board surface adjacent to the test switch and the reset button.

According to some embodiments of the present disclosure, the reset button, the test switch, and the first region are arranged in sequence along a longitudinal axis of the second board surface.

According to some embodiments of the present disclosure, the leakage current detector is located in a region to the left of the test switch, and the driver is located in a region to the left of the reset button and adjacent to the leakage current detector.

According to some embodiments of the present disclosure, the leakage current detector is located in a region to the right of the test switch, and the driver is located in a region to the right of the reset button and adjacent to the leakage current detector.

According to some embodiments of the present disclosure, the leakage current detector is arranged adjacent to the test switch, so that when the test switch of the tester is pressed, a transmission path of a simulated leakage signal on the first shielding conductor structure and the second shielding conductor structure is shorter, facilitating wiring. The driver is arranged adjacent to the leakage current detector, so that a transmission path of a leakage fault signal output by the leakage current detector to the driver is shorter, facilitating wiring.

According to some embodiments of the present disclosure, the current-carrying conductor extends along a longitudinal axis of the first board surface. The current-carrying conductor has an end portion distant from the shielding conductor solder joint, which serves as a power contact terminal for press-contact with the conductive pins, and another end portion proximate to the shielding conductor solder joint, which serves as a power output solder joint for soldering the first current-carrying wire or the second current-carrying wire.

According to some embodiments of the present disclosure, the first shielding conductor structure has a first terminal proximate to the circuit board, a second terminal distant from the first terminal, and a third terminal between the first terminal and the second terminal; the second shielding conductor structure has a fourth terminal proximate to the circuit board, a fifth terminal distant from the fourth terminal, and a sixth terminal between the fourth terminal and the fifth terminal; the third terminal is connected to the sixth terminal; and the first region includes four shielding conductor solder joints, each connected to a corresponding one of the first terminal, the second terminal, the fourth terminal, and the fifth terminal.

According to some embodiments of the present disclosure, the first region includes two shielding conductor solder joints for connection to the third terminal and the sixth terminal, respectively.

According to some embodiments of the present disclosure, the open-circuit detector includes a first switch and a second switch. The first switch includes a first triode and a first resistor for providing a turn-on voltage to the first triode. The second switch includes a second triode and a fourth resistor for providing a turn-on voltage to the second triode. Two terminals of the first resistor are respectively electrically connected to the shielding conductor solder joints corresponding to the first terminal and the fourth terminal, and two terminals of the fourth resistor are respectively electrically connected to the shielding conductor solder joints corresponding to the second terminal and the fifth terminal.

According to some embodiments of the present disclosure, two terminals of the first resistor are respectively electrically connected to the shielding conductor solder joints corresponding to the first terminal and the fifth terminal, and two terminals of the fourth resistor are respectively electrically connected to the shielding conductor solder joints corresponding to the second terminal and the fourth terminal.

According to some embodiments of the present disclosure, the first switch further includes a second resistor and a third resistor, one terminal of the second resistor is connected to the second current-carrying wire, the other terminal of the second resistor is connected to one terminal of the first resistor and an emitter of the first triode, the other terminal of the first resistor is connected to a base of the first triode and one terminal of the third resistor, and the other terminal of the third resistor is connected to the first current-carrying wire. The second switch further includes a fifth resistor and a sixth resistor, one terminal of the fifth resistor is connected to the second current-carrying wire, the other terminal of the fifth resistor is connected to one terminal of the fourth resistor and an emitter of the second triode, the other terminal of the fourth resistor is connected to a base of the second triode and one terminal of the sixth resistor, and the other terminal of the sixth resistor is connected to the first current-carrying wire. Each of the first triode and the second triode has a collector that connects to the driver. The first triode, the second triode, the first resistor, the second resistor, the third resistor, the fourth resistor, the fifth resistor, and the sixth resistor are all arranged in the first region.

According to some embodiments of the present disclosure, the open-circuit detector includes a first switch and a second switch; the first switch includes a first triode and a first voltage dividing unit; and the first voltage dividing unit includes a second resistor, a first resistor, a seventeenth resistor, and a third resistor connected in series in sequence; the second switch includes a second triode and a second voltage dividing unit; and the second voltage dividing unit includes a fifth resistor, a fourth resistor, an eighteenth resistor, and a sixth resistor connected in series in sequence; a connection point between the second resistor and the first resistor is connected to the shielding conductor solder joint corresponding to the first terminal and an emitter of the first triode; a connection point between the first resistor and the seventeenth resistor is connected to a base of the first triode; a connection point between the seventeenth resistor and the third resistor is connected to the shielding conductor solder joint corresponding to the fourth terminal; a connection point between the fifth resistor and the fourth resistor is connected to the shielding conductor solder joint corresponding to the second terminal and an emitter of the second triode; a connection point between the fourth resistor and the eighteenth resistor is connected to a base of the second triode; a connection point between the eighteenth resistor and the sixth resistor is connected to the shielding conductor solder joint corresponding to the fifth terminal; the second resistor and the fifth resistor are connected together and connected to the second current-carrying wire, and the third resistor and the sixth resistor are connected together and connected to the first current-carrying wire; and a collector of the first triode and a collector of the second triode are connected to the driver; and the first triode, the second triode, the first resistor, the second resistor, the third resistor, the fourth resistor, the fifth resistor, the sixth resistor, the seventeenth resistor, and the eighteenth resistor are all arranged in the first region.

According to some embodiments of the present disclosure, the leakage current detector includes a fourteenth resistor, a fifteenth resistor, a third triode, and a third diode, one terminal of the fourteenth resistor is connected to the second current-carrying wire, the other terminal of the fourteenth resistor is connected to one terminal of the fifteenth resistor and a base of the third triode, an emitter of the third triode is connected to a cathode of the third diode, an anode of the third diode is connected to the shielding conductor solder joint corresponding to the sixth terminal, the other terminal of the fifteenth resistor is connected to the first current-carrying wire, and a collector of the third triode is connected to the driver; and the fourteenth resistor, the fifteenth resistor, the third triode, and the third diode are all arranged in a second region to the left of the test switch on the second board surface.

According to some embodiments of the present disclosure, the leakage current detector includes an eleventh resistor and a voltage stabilizing unit, an anode of the voltage stabilizing unit is connected to the driver, a cathode of the voltage stabilizing unit is connected to one terminal of the eleventh resistor, and the other terminal of the eleventh resistor is connected to the shielding conductor solder joint corresponding to the sixth terminal; and the eleventh resistor and the voltage stabilizing unit are both arranged in a second region to the left of the test switch on the second board surface.

According to some embodiments of the present disclosure, the tester further includes an eighth resistor, one terminal of the test switch is connected to a connection point between the second resistor and the fifth resistor, the other terminal of the test switch is connected to one terminal of the eighth resistor, and the other terminal of the eighth resistor is connected to the shielding conductor solder joint corresponding to the third terminal; and the eighth resistor is arranged in the central region of the second board surface and arranged adjacent to the test switch.

According to some embodiments of the present disclosure, the leakage current detector includes a fourteenth resistor, a fifteenth resistor, a sixteenth resistor, and a third triode, one terminal of the fourteenth resistor is connected to the second current-carrying wire, the other terminal of the fourteenth resistor is connected to one terminal of the fifteenth resistor and a base of the third triode, an emitter of the third triode is connected to any one of the shielding conductor solder joints, the other terminal of the fifteenth resistor is connected to the first current-carrying wire, a collector of the third triode is connected to one terminal of the sixteenth resistor, and the other terminal of the sixteenth resistor is connected to the driver; and the fourteenth resistor, the fifteenth resistor, the sixteenth resistor, and the third triode are all arranged in a second region to the left of the test switch on the second board surface.

According to some embodiments of the present disclosure, the leakage current detector includes an eleventh resistor and a voltage stabilizing unit, an anode of the voltage stabilizing unit is connected to the driver, a cathode of the voltage stabilizing unit is connected to one terminal of the eleventh resistor, and the other terminal of the eleventh resistor is connected to any one of the shielding conductor solder joints; and the eleventh resistor and the voltage stabilizing unit are both arranged in a second region to the left of the test switch on the second board surface.

According to some embodiments of the present disclosure, the driver includes a silicon controlled rectifier, a seventh resistor, a tenth resistor, and a first capacitor, the detection-protection apparatus further includes a tripping coil, the second current-carrying wire is connected to one terminal of the tripping coil, the other terminal of the tripping coil is connected to an anode of the silicon controlled rectifier, a control electrode of the silicon controlled rectifier is connected to one terminal of the seventh resistor, one terminal of the tenth resistor, one terminal of the first capacitor, and the leakage current detector, the other terminal of the tenth resistor is connected to the open-circuit detector, and a cathode of the silicon controlled rectifier, the other terminal of the first capacitor, and the other terminal of the seventh resistor are all connected to the first current-carrying wire; and the silicon controlled rectifier, the seventh resistor, the tenth resistor, and the first capacitor are all arranged in a third region to the left of the reset button on the second board surface.

According to some embodiments of the present disclosure, the circuit board has a length dimension in a range of 56 mm±10 mm and a width dimension in a range of 36 mm±10 mm; the first region has a length dimension in a range of 30 mm±3 mm and a width dimension in a range of 8.5 mm±10 mm; a region occupied by the leakage current detector on the second board surface has a length dimension in a range of 10 mm±3 mm and a width dimension in a range of 8 mm±3 mm; and a region occupied by the driver on the second board surface has a length dimension in a range of 15 mm±3 mm and a width dimension in a range of 10 mm±3 mm.

According to some embodiments of the present disclosure, components in the open-circuit detector, the leakage current detector, the driver, and the tripping mechanism are packaged using surface-mount technology or through-hole technology.

According to some embodiments of the present disclosure, the circuit board employs a wiring configuration of a single-layer board, a double-layer board, or a multi-layer board.

According to some embodiments of the present disclosure, the circuit board is processed by wave soldering, reflow soldering, or manual soldering.

In accordance with a second aspect of the present disclosure, an embodiment provides an electrical connection device, including the circuit board according to the embodiments of the first aspect, a power cord, a detection-protection apparatus arranged at the circuit board and connected to the power cord, and a housing enclosing the circuit board, where the housing is provided with conductive pins for accessing a power supply.

According to some embodiments of the present disclosure, a wire clamp for clamping the power cord is provided at a connection between the housing and the power cord; the first shielding conductor structure has a first terminal proximate to the circuit board, a second terminal distant from the first terminal, and a third terminal between the first terminal and the second terminal; and the second shielding conductor structure has a fourth terminal proximate to the circuit board, a fifth terminal distant from the fourth terminal, and a sixth terminal between the fourth terminal and the fifth terminal; and the third terminal and the sixth terminal are electrically connected by one of the following three manners:
manner 1: soldered connection at the wire clamp;
manner 2: soldered connection inside the housing; and
manner 3: routing to the shielding conductor solder joint to achieve electrical connection through the circuit board.

Other features and advantages of the present disclosure are set forth in the following specification, and become partly clear from the specification, or learned by implementing the present disclosure. Objectives and other advantages of the present disclosure may be achieved and obtained by structures particularly indicated in the specification, claims, and accompanying drawings.

### BRIEF DESCRIPTION OF DRAWINGS

Accompanying drawings are used to provide a further understanding of technical schemes of the present disclosure and constitute part of this specification. The drawings are used to explain the technical schemes of the present disclosure together with embodiments of the present disclosure, and do not constitute a limitation on the technical schemes of the present disclosure.

The present disclosure is further described below with reference to the accompanying drawings and the embodiments.

FIG. 1 is a schematic diagram of an overall structure of an electrical connection device according to an embodiment of the present disclosure;

FIG. 2 is a circuit schematic diagram of a detection-protection apparatus for a power cord according to an embodiment of the present disclosure;

FIG. 3 is a circuit schematic diagram of a detection-protection apparatus for a power cord according to another embodiment of the present disclosure;

FIG. 4 is a circuit schematic diagram of a detection-protection apparatus for a power cord according to still another embodiment of the present disclosure;

FIG. 5 is a circuit schematic diagram of a detection-protection apparatus for a power cord according to yet another embodiment of the present disclosure;

FIG. 6 is a circuit schematic diagram of a detection-protection apparatus for a power cord according to still yet another embodiment of the present disclosure;

FIG. 7 is a circuit schematic diagram of a detection-protection apparatus for a power cord according to still another embodiment of the present disclosure;

FIG. 8 is a circuit schematic diagram of a detection-protection apparatus for a power cord according to still another embodiment of the present disclosure;

FIG. 9 is a circuit schematic diagram of a detection-protection apparatus for a power cord according to still another embodiment of the present disclosure;

FIG. 10 is a schematic layout diagram of a first board surface of a circuit board of an electrical connection device according to an embodiment of the present disclosure;

FIG. 11 is a schematic layout diagram of a second board surface of a circuit board of an electrical connection device according to an embodiment of the present disclosure;

FIG. 12 is a schematic layout diagram of a first board surface of a circuit board of an electrical connection device according to another embodiment of the present disclosure; and

FIG. 13 is a schematic layout diagram of a second board surface of a circuit board of an electrical connection device according to another embodiment of the present disclosure.

### DETAILED DESCRIPTION

Embodiments of the present disclosure are described in detail below, examples of which are illustrated in the accompanying drawings. The function of the accompanying drawings is to supplement the description of the text part of the description with graphics, such that those having ordinary skills in the art can intuitively and vividly understand each technical feature and the overall technical scheme of the present disclosure, but the accompanying drawings are not intended to be construed as limiting the scope of the present disclosure.

In the description of the present disclosure, “several” means one or more, “multiple (plurality of)” means two or more, “greater than,” “less than,” “exceeding,” and the like are understood as excluding the given number, while “above,” “below,” “within,” and the like are understood as including the given number. “At least one” means one or more, and the expression “at least one of the following ...” and similar expressions refer to any combination of the items, including any combination of a single item or a plurality of items. Any reference to “first,” “second,” and the like is used merely for distinguishing technical features and should not be construed as indicating or implying relative importance, implicitly indicating the number of the indicated technical features, or implicitly indicating the order of precedence of the indicated technical features.

In the description of the present disclosure, unless otherwise expressly limited, terms such as “arranged,” “mounted,” “connected,” and the like should be understood in a broad sense. A person skilled in the art can reasonably determine the specific meanings of these terms in the present disclosure based on the specific context of the technical schemes. For example, the term “connected” may refer to a mechanical connection, an electrical connection, or a connection enabling communication with each other; it may be a direct connection, or an indirect connection via an intermediate medium.

It should be noted that the technical features involved in the various embodiments of the present disclosure described below may be combined with each other if not in conflict.

A leakage circuit detector interrupter (LCDI) is a power supply connection device for electrical appliances that monitors leakage current in a power cord assembly through dedicated leakage current detection conductors. When a specified level of leakage current is detected, the LCDI interrupts the electrical connection to the electrical appliances to ensure safe operation. In recent years, in addition to monitoring leakage current along the power cord, LCDI devices have been required to meet more advanced safety demands—for instance, the capability to detect whether the leakage current detection conductor itself is in an open-circuit condition. Currently, as the safety detection requirements for detection-protection apparatuss of power cords become increasingly higher, the detection-protection apparatuss include more and more circuit modules and components. Consequently, the layout of the circuit board of the electrical connection device also faces increasing challenges, such as difficulties in circuit board wiring, susceptibility of electrical signals transmitted on the circuit board to interference, and the need for relatively large board dimensions.

In view of the above, embodiments of the present application provide a circuit board layout for an electrical connection device and an electrical connection device, which can simplify routing, enhance anti-interference capability, and minimize the size of the circuit board as much as possible.

Embodiments of the present disclosure are further described in detail below with reference to accompanying drawings.

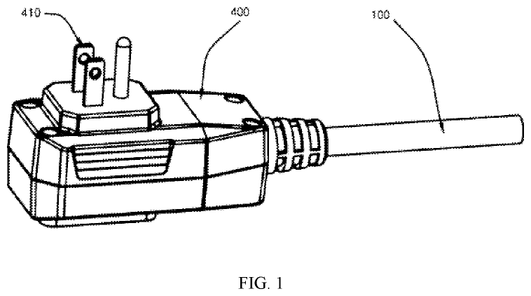

FIG. 1 is a schematic diagram of an overall structure of an electrical connection device according to an embodiment of the present disclosure. The electrical connection device includes a power cord 100, a detection-protection apparatus arranged at the circuit board and connected to the power cord 100, and a housing 400 enclosing the circuit board; and the housing 400 is provided with conductive pins 410 for accessing a power supply. Because the circuit board is located inside the housing 400, the circuit board is not shown in FIG. 1.

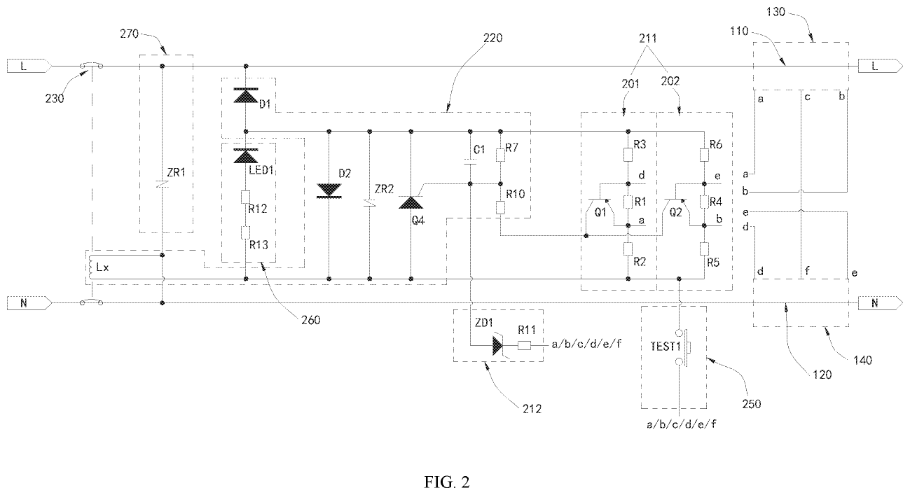

FIG. 2 to FIG. 9 are circuit schematic diagrams of a detection-protection apparatus for a power cord 100 according to some embodiments of the present disclosure.

In an embodiment, the power cord 100 includes a first current-carrying wire 110, a second current-carrying wire 120, a first shielding conductor structure 130 wrapping the first current-carrying wire 110, and a second shielding conductor structure 140 wrapping the second current-carrying wire 120. The first shielding conductor structure 130has a first terminal a proximate to the circuit board, a second terminal b distant from the first terminal a, and a third terminal c between the first terminal a and the second terminal b; and the second shielding conductor structure 140 has a fourth terminal d proximate to the circuit board, a fifth terminal e distant from the fourth terminal d, and a sixth terminal f between the fourth terminal d and the fifth terminal e; and the third terminal c is connected to the sixth terminal f. It can be understood that the first shielding conductor structure 130 covers the first current-carrying wire 110 so as to collect a leakage signal of the first current-carrying wire 110, and the second shielding conductor structure 140 covers the second current-carrying wire 120 so as to collect a leakage signal of the second current-carrying wire 120. On this basis, the third terminal c in the center of the first shielding conductor structure 130 is connected to the sixth terminal f in the second shielding conductor structure 140, so that an association point is built between the shielding conductor structures of the first current-carrying wire 110 and the second current-carrying wire 120. In this way. the two shielding conductor structures are no longer independent and separate. Therefore, the first shielding conductor structure 130 and the second shielding conductor structure 140 can establish a plurality of different detection paths for open-circuit detection, such as a detection path from the first terminal a of the first shielding conductor structure 130 to the third terminal c of the first shielding conductor structure 130, then to the sixth terminal f of the second shielding conductor structure 140, and finally to the fourth terminal d of the second shielding conductor structure 140; a detection path from the first terminal a of the first shielding conductor structure 130 to the third terminal c of the first shielding conductor structure 130, then to the sixth terminal f of the second shielding conductor structure 140, and finally to the fifth terminal e of the second shielding conductor structure 140; a detection path from the second terminal b of the first shielding conductor structure 130 to the third terminal c of the first shielding conductor structure 130, then to the sixth terminal f of the second shielding conductor structure 140, and finally to the fourth terminal d of the second shielding conductor structure 140; and a detection path from the second terminal b of the first shielding conductor structure 130 to the third terminal c of the first shielding conductor structure 130, then to the sixth terminal f of the second shielding conductor structure 140, and finally to the fifth terminal e of the second shielding conductor structure 140.

The detection-protection apparatus includes an open-circuit detector 211, a leakage current detector 212, a driver 220, a tripping mechanism 230, a tester 250, an LED indicator 260, and a Surge Protective Device 270.

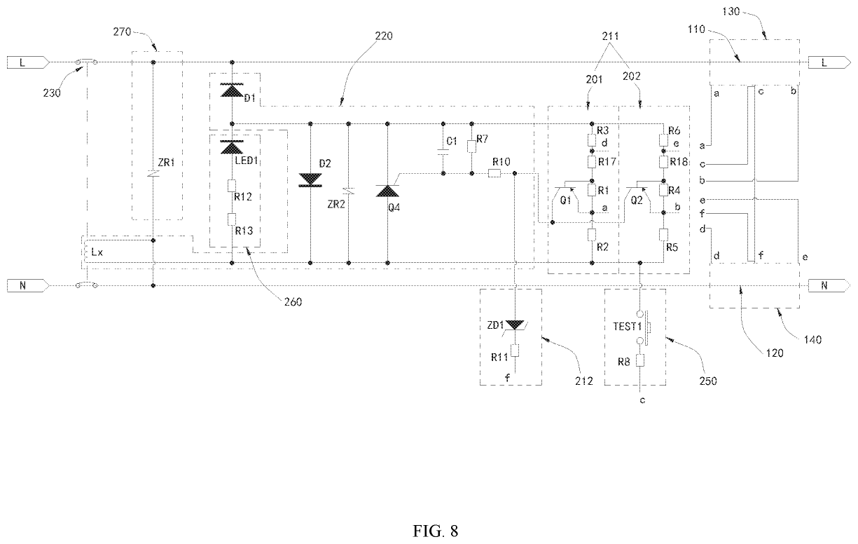

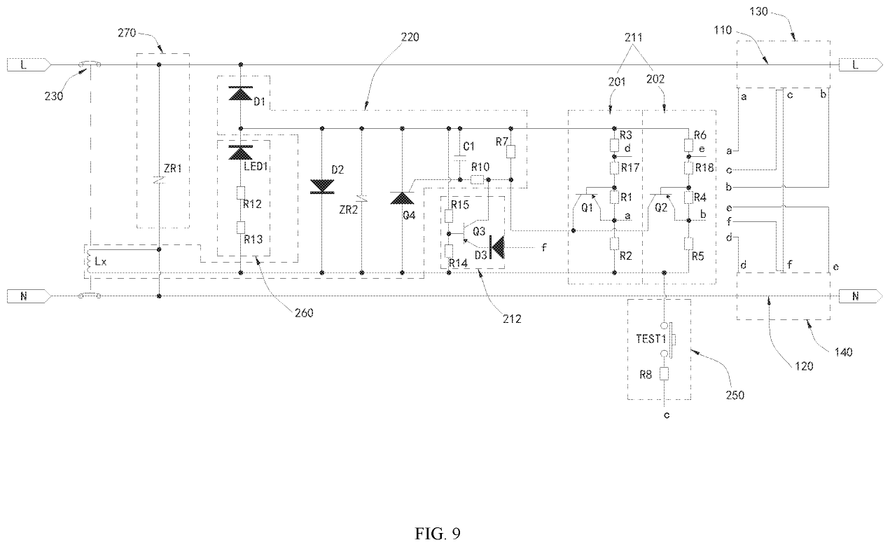

The open-circuit detector 211 includes a first switch 201 and a second switch 202. In the embodiments shown in FIG. 2 to FIG. 7, the first switch 201 includes a first triode Q1, a first resistor R1, a second resistor R2, and a third resistor R3, and the second switch 202 includes a second triode Q2, a fourth resistor R4, a fifth resistor R5, and a sixth resistor R6. In the embodiments shown in FIG. 8 and FIG. 9, the first switch 201 includes a first triode Q1 and a first voltage dividing unit, and the first voltage dividing unit includes a first resistor R1, a second resistor R2, a third resistor R3, and a seventeenth resistor R17; and the second switch 202 includes a second triode Q2 and a second voltage dividing unit, and the second voltage dividing unit includes a fourth resistor R4, a fifth resistor R5, a sixth resistor R6, and an eighteenth resistor R18.

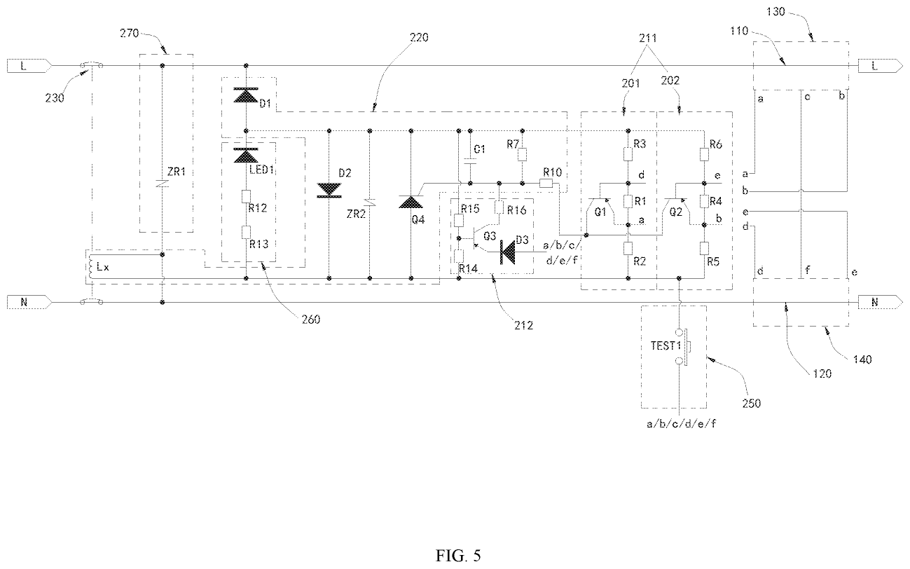

The leakage current detector 212 includes, in the embodiments shown in FIG. 2 to FIG. 4 and FIG. 8, a voltage stabilizing unit ZD1 and an eleventh resistor R11. The leakage current detector 212 includes, in the embodiments shown in FIG. 5 to FIG. 7, a third triode Q3, a fourteenth resistor R14, a fifteenth resistor R15, a sixteenth resistor R16, and a third diode D3. The leakage current detector 212 includes, in the embodiment shown in FIG. 9, a third triode Q3, a fourteenth resistor R14, a fifteenth resistor R15, and a third diode D3.

The driver 220 includes a silicon controlled rectifier Q4, a seventh resistor R7, a tenth resistor R10, and a first capacitor C1.

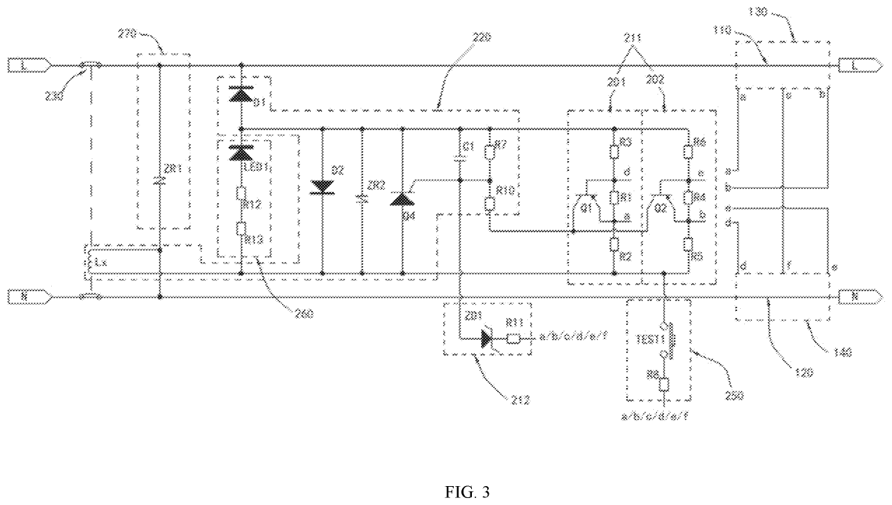

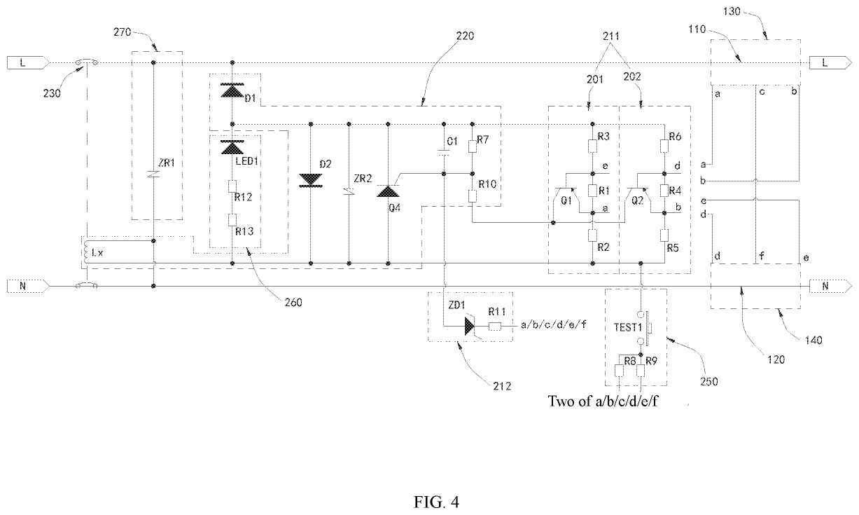

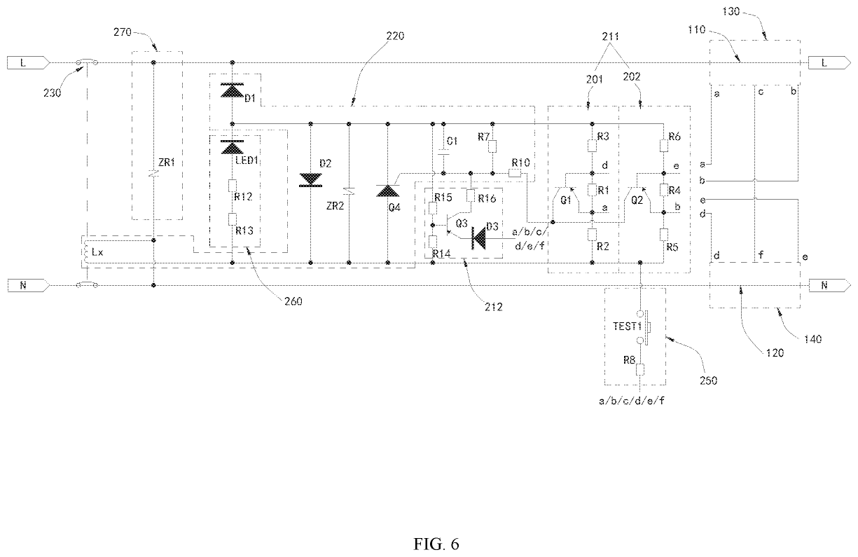

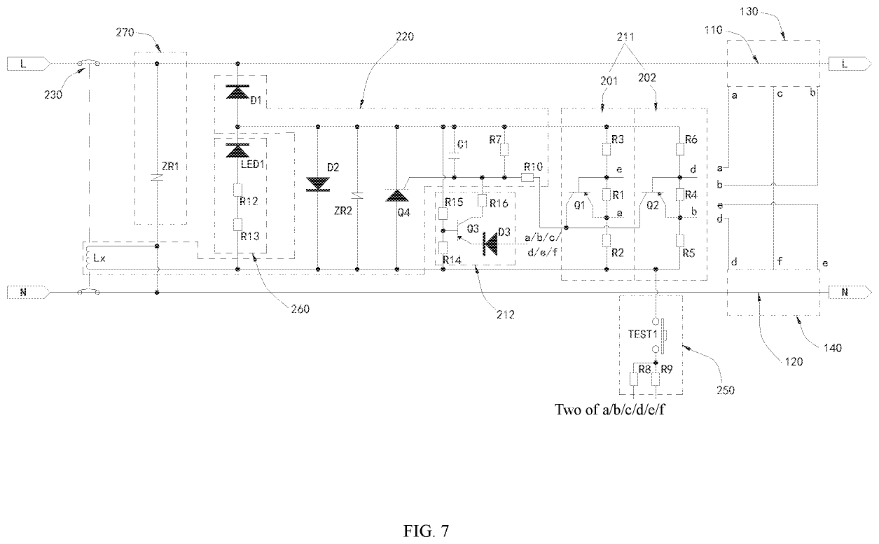

The tester 250 includes, in the embodiments shown in FIG. 2 and FIG. 5, a test switch TEST1. The tester 250 includes, in the embodiments shown in FIG. 3, FIG. 6, FIG. 8, and FIG. 9, a test switch TEST1 and an eighth resistor R8. The tester 250 includes, in the embodiments shown in FIG. 4 and FIG. 7, a test switch TEST1, an eighth resistor R8, and a ninth resistor R9.

The LED indicator 260 includes a twelfth resistor R12, a thirteenth resistor R13, and a light-emitting diode LED1.

The Surge Protective Device 270 includes a first varistor ZR1.

The detection-protection apparatus further includes a tripping coil Lx, a first diode D1, a second diode D2, and a second varistor ZR2.

Specifically, in the embodiments shown in FIG. 2 to FIG. 7, connection relationships of the various circuit components are as follows.

The second current-carrying wire 120 is connected to one terminal of the tripping coil Lx and one terminal of the first varistor ZR1, the other terminal of the first varistor ZR1 is connected to the first current-carrying wire 110, and the other terminal of the tripping coil Lx is connected to one terminal of the thirteenth resistor R13, a cathode of the second diode D2, one terminal of the second varistor ZR2, an anode of the silicon controlled rectifier Q4, one terminal of the second resistor R2, one terminal of the fifth resistor R5, and one terminal of the test switch TEST1. The other terminal of the thirteenth resistor R13 is connected to one terminal of the twelfth resistor R12, and the other terminal of the twelfth resistor R12 is connected to an anode of the light-emitting diode LED1. The other terminal of the second resistor R2 is connected to one terminal of the first resistor R1 and an emitter of the first triode Q1. The other terminal of the first resistor R1 is connected to one terminal of the third resistor R3 and a base of the first triode Q1. The other terminal of the fifth resistor R5 is connected to one terminal of the fourth resistor R4 and an emitter of the second triode Q2. The other terminal of the fourth resistor R4 is connected to one terminal of the sixth resistor R6 and a base of the second triode Q2. A collector of the first triode Q1 and a collector of the second triode Q2 are connected together and then connected to one terminal of the tenth resistor R10. The other terminal of the tenth resistor R10 is connected to one terminal of the seventh resistor R7, one terminal of the first capacitor C1, and a control electrode of the silicon controlled rectifier Q4. The other terminal of the sixth resistor R6, the other terminal of the third resistor R3, the other terminal of the seventh resistor R7, the other terminal of the first capacitor C1, a cathode of the silicon controlled rectifier Q4, the other terminal of the second varistor ZR2, an anode of the second diode D2, and a cathode of the light-emitting diode LED1 are all connected to an anode of the first diode D1, and a cathode of the first diode D1 is connected to the first current-carrying wire 110.

Regarding the first resistor R1, in the embodiments of FIG. 2 and FIG. 5, one terminal of the first resistor R1 is further connected to the first terminal a, and the other terminal of the first resistor R1 is further connected to the fourth terminal d; and in the embodiments of FIG. 4 and FIG. 7, one terminal of the first resistor R1 is further connected to the first terminal a, and the other terminal of the first resistor R1 is further connected to the fifth terminal e.

Regarding the fourth resistor R4, in the embodiments of FIG. 2 and FIG. 5, one terminal of the fourth resistor R4 is further connected to the second terminal b, and the other terminal of the fourth resistor R4 is further connected to the fifth terminal e; and in the embodiments of FIG. 4 and FIG. 7, one terminal of the fourth resistor R4 is further connected to the second terminal b, and the other terminal of the fourth resistor R4 is further connected to the fourth terminal d.

Regarding the leakage current detector 212, in the embodiments shown in FIG. 2 and FIG. 4, an anode of the voltage stabilizing unit ZD1 is connected to the control electrode of the silicon controlled rectifier Q4, a cathode of the voltage stabilizing unit ZD1 is connected to one terminal of the eleventh resistor R11, and the other terminal of the eleventh resistor R11 is connected to any one of the first terminal a, the second terminal b, the third terminal c, the fourth terminal d, the fifth terminal e, and the sixth terminal f; and in the embodiments shown in FIG. 5 and FIG. 7, a base of the third triode Q3 is connected to one terminal of the fourteenth resistor R14 and one terminal of the fifteenth resistor R15, the other terminal of the fourteenth resistor R14 is connected to a connection point between the tripping coil Lx and the anode of the silicon controlled rectifier Q4, the other terminal of the fifteenth resistor R15 is connected to a connection point between the cathode of the silicon controlled rectifier Q4 and the anode of the first diode D1, a collector of the third triode Q3 is connected to one terminal of the sixteenth resistor R16, and the other terminal of the sixteenth resistor R16 is connected to the control electrode of the silicon controlled rectifier Q4; and an emitter of the third triode Q3 is connected to a cathode of the third diode D3, and an anode of the third diode D3 is connected to any one of the first terminal a, the second terminal b, the third terminal c, the fourth terminal d, the fifth terminal e, and the sixth terminal f.

Regarding the tester 250, in the embodiments shown in FIG. 2 and FIG. 5, the other terminal of the test switch TEST1 is connected to any one of the first terminal a, the second terminal b, the third terminal c, the fourth terminal d, the fifth terminal e, and the sixth terminal f; in the embodiments shown in FIG. 3 and FIG. 6, the other terminal of the test switch TEST1 is connected to one terminal of the eighth resistor R8, and the other terminal of the eighth resistor R8 is connected to any one of the first terminal a, the second terminal b, the third terminal c, the fourth terminal d, the fifth terminal e, and the sixth terminal f; and in the embodiments shown in FIG. 4 and FIG. 7, the other terminal of the test switch TEST1 is connected to one terminal of the eighth resistor R8 and one terminal of the ninth resistor R9, and the other terminal of the eighth resistor R8 and the other terminal of the ninth resistor R9 are connected to any two of the first terminal a, the second terminal b, the third terminal c, the fourth terminal d, the fifth terminal e, and the sixth terminal f.

In addition, in the embodiments shown in FIG. 8 and FIG. 9, connection relationships of the various circuit components are as follows.

The second current-carrying wire 120 is connected to one terminal of the tripping coil Lx and one terminal of the first varistor ZR1, the other terminal of the first varistor ZR1 is connected to the first current-carrying wire 110, and the other terminal of the tripping coil Lx is connected to one terminal of the thirteenth resistor R13, a cathode of the second diode D2, one terminal of the second varistor ZR2, an anode of the silicon controlled rectifier Q4, one terminal of the second resistor R2, one terminal of the fifth resistor R5, and one terminal of the test switch TEST1. The other terminal of the thirteenth resistor R13 is connected to one terminal of the twelfth resistor R12, and the other terminal of the twelfth resistor R12 is connected to an anode of the light-emitting diode LED1. The other terminal of the second resistor R2 is connected to one terminal of the first resistor R1, an emitter of the first triode Q1, and the first terminal a. The other terminal of the first resistor R1 is connected to one terminal of the seventeenth resistor R17 and a base of the first triode Q1, and the other terminal of the seventeenth resistor R17 is connected to the fourth terminal d. The other terminal of the fifth resistor R5 is connected to one terminal of the fourth resistor R4, an emitter of the second triode Q2, and the second terminal b. The other terminal of the fourth resistor R4 is connected to one terminal of the eighteenth resistor R18 and a base of the second triode Q2, and the other terminal of the eighteenth resistor R18 is connected to the fifth terminal e. A collector of the first triode Q1 and a collector of the second triode Q2 are connected together and then connected to one terminal of the tenth resistor R10 and one terminal of the seventh resistor R7. The other terminal of the tenth resistor R10 is connected to one terminal of the first capacitor C1 and a control electrode of the silicon controlled rectifier Q4. The other terminal of the sixth resistor R6, the other terminal of the third resistor R3, the other terminal of the seventh resistor R7, the other terminal of the first capacitor C1, a cathode of the silicon controlled rectifier Q4, the other terminal of the second varistor ZR2, an anode of the second diode D2, and a cathode of the light-emitting diode LED1 are all connected to an anode of the first diode D1, and a cathode of the first diode D1 is connected to the first current-carrying wire 110.

Regarding the leakage current detector 212, in the embodiment shown in FIG. 8, an anode of the voltage stabilizing unit ZD1 is connected to a connection point among the tenth resistor R10, the collector of the first triode Q1, and the collector of the second triode Q2, a cathode of the voltage stabilizing unit ZD1 is connected to one terminal of the eleventh resistor R11, and the other terminal of the eleventh resistor R11 is connected to any one of the first terminal a, the second terminal b, the third terminal c, the fourth terminal d, the fifth terminal e, and the sixth terminal f, where the other terminal of the eleventh resistor R11 is, in some embodiments, connected to the sixth terminal f; and in the embodiment shown in FIG. 9, a base of the third triode Q3 is connected to one terminal of the fourteenth resistor R14 and one terminal of the fifteenth resistor R15, the other terminal of the fourteenth resistor R14 is connected to a connection point between the tripping coil Lx and the anode of the silicon controlled rectifier Q4, the other terminal of the fifteenth resistor R15 is connected to a connection point between the cathode of the silicon controlled rectifier Q4 and the anode of the first diode D1, and a collector of the third triode Q3 is connected to a connection point among the tenth resistor R10, the collector of the first triode Q1, and the collector of the second triode Q2; and an emitter of the third triode Q3 is connected to a cathode of the third diode D3, and an anode of the third diode D3 is connected to any one of the first terminal a, the second terminal b, the third terminal c, the fourth terminal d, the fifth terminal e, and the sixth terminal f, where the anode of the third diode D3 is, in some embodiments, connected to the sixth terminal f.

Regarding the tester 250, in the embodiments shown in FIG. 8 and FIG. 9, the other terminal of the test switch TEST1 is connected to one terminal of the eighth resistor R8, and the other terminal of the eighth resistor R8 is connected to any one of the first terminal a, the second terminal b, the third terminal c, the fourth terminal d, the fifth terminal e, and the sixth terminal f, where the other terminal of the eighth resistor R8 is, in some embodiments, connected to the third terminal c.

Subsequently, operation of the detection-protection apparatus under various leakage and open-circuit cases is described using the embodiment shown in FIG. 5 as an example.

1. In a case that a leakage signal of the first current-carrying wire 110 is transmitted to the first shielding conductor structure 130.

After the first shielding conductor structure 130 receives the leakage signal, the third triode Q3 is turned on, forming a conduction path of the first current-carrying wire 110—the first shielding conductor structure 130—the third diode D3—the third triode Q3—the sixteenth resistor R16—the seventh resistor R7—the second diode D2—the tripping coil Lx—the second current-carrying wire 120.

Accordingly, a voltage at the control electrode of the silicon controlled rectifier Q4 rises. During the negative half cycle of an AC power supply, that is, when a level of the second current-carrying wire 120 is higher than a level of the first current-carrying wire 110, the silicon controlled rectifier Q4 is turned on, forming a high-current path of the second current-carrying wire 120—the tripping coil Lx—the silicon controlled rectifier Q4—the first diode D1—the first current-carrying wire 110.

The tripping coil Lx generates a strong electromagnetic force, thereby driving the tripping mechanism 230 to disconnect power connection between an input terminal and an output terminal of the power cord.

2. In a case that a leakage signal of the second current-carrying wire 120 is transmitted to the second shielding conductor structure 140.

After the second shielding conductor structure 140 receives the leakage signal, the third triode Q3 is turned on, forming a conduction path of the second current-carrying wire 120—the second shielding conductor structure 140—the third diode D3—the third triode Q3—the sixteenth resistor R16—the seventh resistor R7—the first diode D1—the first current-carrying wire 110.

Accordingly, a voltage at the control electrode of the silicon controlled rectifier Q4 rises. During the negative half cycle of an AC power supply, that is, when a level of the second current-carrying wire 120 is higher than a level of the first current-carrying wire 110, the silicon controlled rectifier Q4 is turned on, forming a high-current path of the second current-carrying wire 120—the tripping coil Lx—the silicon controlled rectifier Q4—the first diode D1—the first current-carrying wire 110.

The tripping coil Lx generates a strong electromagnetic force, thereby driving the tripping mechanism 230 to disconnect power connection between an input terminal and an output terminal of the power cord.

3. In a case that a portion of the first shielding conductor structure 130 between the first terminal a and the third terminal c is open-circuited.

A short-circuit path between the first terminal a and the fourth terminal d is disconnected, and the two terminals of the first resistor R1 are no longer short-circuited. The two terminals of the fourth resistor R4 remain short-circuited by a conduction path of the second terminal b—the third terminal c—the sixth terminal f—the fifth terminal e. It should be noted that a conduction path of the second terminal b—the third terminal c—the sixth terminal f—the fourth terminal d also exists.

A conduction path of the second current-carrying wire 120—the tripping coil Lx—the second resistor R2—the first resistor R1—the third resistor R3—the first diode D1—the first current-carrying wire 110 is formed.

This turns on the first triode Q1, while the second triode Q2 remains off. A conduction path of the second current-carrying wire 120—the tripping coil Lx—the second resistor R 2—the first triode Q1—the tenth resistor R10—the seventh resistor R7—the first diode D1—the first current-carrying wire 110 is formed.

Accordingly, a voltage at the control electrode of the silicon controlled rectifier Q4 rises. During the negative half cycle of an AC power supply, that is, when a level of the second current-carrying wire 120 is higher than a level of the first current-carrying wire 110, the silicon controlled rectifier Q4 is turned on, forming a high-current path of the second current-carrying wire 120—the tripping coil Lx—the silicon controlled rectifier Q4—the first diode D1—the first current-carrying wire 110.

The tripping coil Lx generates a strong electromagnetic force, thereby driving the tripping mechanism 230 to disconnect power connection between an input terminal and an output terminal of the power cord.

4. In a case that a portion of the first shielding conductor structure 130 between the second terminal b and the third terminal c is open-circuited.

A short-circuit path between the second terminal b and the fifth terminal e is disconnected, and the two terminals of the fourth resistor R4 are no longer short-circuited. The two terminals of the first resistor R1 remain short-circuited by a conduction path of the first terminal a—the third terminal c—the sixth terminal f—the fourth terminal d. It should be noted that a conduction path of the first terminal a—the third terminal c—the sixth terminal f—the fifth terminal e also exists.

A conduction path of the second current-carrying wire 120—the tripping coil Lx—the fifth resistor R5—the fourth resistor R4—the sixth resistor R6—the first diode D1—the first current-carrying wire 110 is formed.

This turns on the second triode Q2, while the first triode Q1 remains off. A conduction path of the second current-carrying wire 120—the tripping coil Lx—the fifth resistor R5—the second triode Q2—the tenth resistor R10—the seventh resistor R7—the first diode D1—the first current-carrying wire 110 is formed.

Accordingly, a voltage at the control electrode of the silicon controlled rectifier Q4 rises. During the negative half cycle of an AC power supply, that is, when a level of the second current-carrying wire 120 is higher than a level of the first current-carrying wire 110, the silicon controlled rectifier Q4 is turned on, forming a high-current path of the second current-carrying wire 120—the tripping coil Lx—the silicon controlled rectifier Q4—the first diode D1—the first current-carrying wire 110.

The tripping coil Lx generates a strong electromagnetic force, thereby driving the tripping mechanism 230 to disconnect power connection between an input terminal and an output terminal of the power cord.

5. In a case that a connecting conductor between the third terminal c and the sixth terminal f is open-circuited.

A short-circuit path between the first terminal a and the fourth terminal d is disconnected, and the two terminals of the first resistor R1 are no longer short-circuited. A short-circuit path between the second terminal b and the fifth terminal e is disconnected, and the two terminals of the fourth resistor R4 are no longer short-circuited.

A conduction path of the second current-carrying wire 120—the tripping coil Lx—the second resistor R2—the first resistor R1—the third resistor R3—the first diode D1—the first current-carrying wire 110 is formed, and a conduction path of the second current-carrying wire 120—the tripping coil Lx—the fifth resistor R5—the fourth resistor R4—the sixth resistor R6—the first diode D1—the first current-carrying wire 110 is formed.

This turns on both the first triode Q1 and the second triode Q2. A conduction path of the second current-carrying wire 120—the tripping coil Lx—the second resistor R 2—the first triode Q1—the tenth resistor R10—the seventh resistor R7—the first diode D1—the first current-carrying wire 110 is formed, and a conduction path of the second current-carrying wire 120—the tripping coil Lx—the fifth resistor R5—the second triode Q2—the tenth resistor R10—the seventh resistor R7—the first diode D1—the first current-carrying wire 110 is formed.

Accordingly, a voltage at the control electrode of the silicon controlled rectifier Q4 rises. During the negative half cycle of an AC power supply, that is, when a level of the second current-carrying wire 120 is higher than a level of the first current-carrying wire 110, the silicon controlled rectifier Q4 is turned on, forming a high-current path of the second current-carrying wire 120—the tripping coil Lx—the silicon controlled rectifier Q4—the first diode D1—the first current-carrying wire 110.

The tripping coil Lx generates a strong electromagnetic force, thereby driving the tripping mechanism 230 to disconnect power connection between an input terminal and an output terminal of the power cord.

6. In a case that a portion of the second shielding conductor structure 140 between the fourth terminal d and the sixth terminal f is open-circuited.

A short-circuit path between the first terminal a and the fourth terminal d is disconnected, and the two terminals of the first resistor R1 are no longer short-circuited. The two terminals of the fourth resistor R4 remain short-circuited by a conduction path of the second terminal b—the third terminal c—the sixth terminal f—the fifth terminal e. It should be noted that a conduction path of the first terminal a—the third terminal c—the sixth terminal f—the fifth terminal e also exists.

A conduction path of the second current-carrying wire 120—the tripping coil Lx—the second resistor R2—the first resistor R1—the third resistor R3—the first diode D1—the first current-carrying wire 110 is formed.

This turns on the first triode Q1, while the second triode Q2 remains off. A conduction path of the second current-carrying wire 120—the tripping coil Lx—the second resistor R2—the first triode Q1—the tenth resistor R10—the seventh resistor R7—the first diode D1—the first current-carrying wire 110 is formed.

Accordingly, a voltage at the control electrode of the silicon controlled rectifier Q4 rises. During the negative half cycle of an AC power supply, that is, when a level of the second current-carrying wire 120 is higher than a level of the first current-carrying wire 110, the silicon controlled rectifier Q4 is turned on, forming a high-current path of the second current-carrying wire 120—the tripping coil Lx—the silicon controlled rectifier Q4—the first diode D1—the first current-carrying wire 110.

The tripping coil Lx generates a strong electromagnetic force, thereby driving the tripping mechanism 230 to disconnect power connection between an input terminal and an output terminal of the power cord.

7. In a case that a portion of the second shielding conductor structure 140 between the fifth terminal e and the sixth terminal f is open-circuited.

A short-circuit path between the second terminal b and the fifth terminal e is disconnected, and the two terminals of the fourth resistor R4 are no longer short-circuited. The two terminals of the first resistor R1 remain short-circuited by a conduction path of the first terminal a—the third terminal c—the sixth terminal f—the fourth terminal d. It should be noted that a conduction path of the second terminal b—the third terminal c—the sixth terminal f—the fourth terminal d also exists.

A conduction path of the second current-carrying wire 120—the tripping coil Lx—the fifth resistor R5—the fourth resistor R4—the sixth resistor R6—the first diode D1—the first current-carrying wire 110 is formed.

This turns on the second triode Q2, while the first triode Q1 remains off. A conduction path of the second current-carrying wire 120—the tripping coil Lx—the fifth resistor R 5—the second triode Q2—the tenth resistor R10—the seventh resistor R7—the first diode D1—the first current-carrying wire 110 is formed.

Accordingly, a voltage at the control electrode of the silicon controlled rectifier Q4 rises. During the negative half cycle of an AC power supply, that is, when a level of the second current-carrying wire 120 is higher than a level of the first current-carrying wire 110, the silicon controlled rectifier Q4 is turned on, forming a high-current path of the second current-carrying wire 120—the tripping coil Lx—the silicon controlled rectifier Q4—the first diode D1—the first current-carrying wire 110.

The tripping coil Lx generates a strong electromagnetic force, thereby driving the tripping mechanism 230 to disconnect power connection between an input terminal and an output terminal of the power cord.

8. In a case that the test switch TEST1 is pressed.

The test switch TEST1 simulates a leakage signal of the second current-carrying wire 120 being transmitted to the first shielding conductor structure 130 or the second shielding conductor structure 140:

After the first shielding conductor structure 130 or the second shielding conductor structure 140 receives the leakage signal, the third triode Q3 is turned on, forming a conduction path of the second current-carrying wire 120—the tripping coil Lx—the test switch TEST 1—the first shielding conductor structure 130/the second shielding conductor structure 140—the third diode D3—the third triode Q3—the sixteenth resistor R16—the seventh resistor R7—the first diode D1—the first current-carrying wire 110.

Accordingly, a voltage at the control electrode of the silicon controlled rectifier Q4 rises. During the negative half cycle of an AC power supply, that is, when a level of the second current-carrying wire 120 is higher than a level of the first current-carrying wire 110, the silicon controlled rectifier Q4 is turned on, forming a high-current path of the second current-carrying wire 120—the tripping coil Lx—the silicon controlled rectifier Q4—the first diode D1—the first current-carrying wire 110.

The tripping coil Lx generates a strong electromagnetic force, thereby driving the tripping mechanism 230 to disconnect power connection between an input terminal and an output terminal of the power cord.

In addition, operation of the detection-protection apparatus provided in the embodiments of the present disclosure under various leakage and open-circuit cases is described using the embodiment shown in FIG. 8 as an example.

1. In a case that a leakage signal of the first current-carrying wire 110 is transmitted to the first shielding conductor structure 130.

After the first shielding conductor structure 130 receives the leakage signal, the signal is transmitted to the sixth terminal f, thereby causing the voltage stabilizing unit ZD1 to break down, forming a conduction path of the first current-carrying wire 110—the first shielding conductor structure 130—the eleventh resistor R11—the voltage stabilizing unit ZD1—the seventh resistor R7—the second diode D2—the tripping coil Lx—the second current-carrying wire 120.

Accordingly, a voltage at the control electrode of the silicon controlled rectifier Q4 rises. During the negative half cycle of an AC power supply, that is, when a level of the second current-carrying wire 120 is higher than a level of the first current-carrying wire 110, the silicon controlled rectifier Q4 is turned on, forming a high-current path of the second current-carrying wire 120—the tripping coil Lx—the silicon controlled rectifier Q4—the first diode D1—the first current-carrying wire 110.

The tripping coil Lx generates a strong electromagnetic force, thereby driving the tripping mechanism 230 to disconnect power connection between an input terminal and an output terminal of the power cord.

2. In a case that a leakage signal of the second current-carrying wire 120 is transmitted to the second shielding conductor structure 140.

After the second shielding conductor structure 140 receives the leakage signal, the signal is transmitted to the sixth terminal f, thereby causing the voltage stabilizing unit ZD1 to break down, forming a conduction path of the second current-carrying wire 120—the second shielding conductor structure 140—the eleventh resistor R11—the voltage stabilizing unit ZD1—the seventh resistor R7—the first diode D1—the first current-carrying wire 110.

Accordingly, a voltage at the control electrode of the silicon controlled rectifier Q4 rises. During the negative half cycle of an AC power supply, that is, when a level of the second current-carrying wire 120 is higher than a level of the first current-carrying wire 110, the silicon controlled rectifier Q4 is turned on, forming a high-current path of the second current-carrying wire 120—the tripping coil Lx—the silicon controlled rectifier Q4—the first diode D1—the first current-carrying wire 110.

The tripping coil Lx generates a strong electromagnetic force, thereby driving the tripping mechanism 230 to disconnect power connection between an input terminal and an output terminal of the power cord.

3. In a case that a portion of the first shielding conductor structure 130 between the first terminal a and the third terminal c is open-circuited.

A short-circuit path between the first terminal a and the fourth terminal d is disconnected, and two terminals of a first biasing unit formed by the first resistor R1 and the seventeenth resistor R17 connected in series are no longer short-circuited. Two terminals of a second biasing unit formed by the fourth resistor R4 and the eighteenth resistor R18 connected in series remain short-circuited by a conduction path of the second terminal b—the third terminal c—the sixth terminal f—the fifth terminal e. It should be noted that a conduction path of the second terminal b—the third terminal c—the sixth terminal f—the fourth terminal d also exists.

A conduction path of the second current-carrying wire 120—the tripping coil Lx—the second resistor R2—the first resistor R1—the seventeenth resistor R17—the third resistor R3—the first diode D1—the first current-carrying wire 110 is formed.

This turns on the first triode Q1, while the second triode Q2 remains off. A conduction path of the second current-carrying wire 120—the tripping coil Lx—the second resistor R2—the first triode Q1—the seventh resistor R7—the first diode D1—the first current-carrying wire 110 is formed.

Accordingly, a voltage at the control electrode of the silicon controlled rectifier Q4 rises. During the negative half cycle of an AC power supply, that is, when a level of the second current-carrying wire 120 is higher than a level of the first current-carrying wire 110, the silicon controlled rectifier Q4 is turned on, forming a high-current path of the second current-carrying wire 120—the tripping coil Lx—the silicon controlled rectifier Q4—the first diode D1—the first current-carrying wire 110.

The tripping coil Lx generates a strong electromagnetic force, thereby driving the tripping mechanism 230 to disconnect power connection between an input terminal and an output terminal of the power cord.

4. In a case that a portion of the first shielding conductor structure 130 between the second terminal b and the third terminal c is open-circuited.

A short-circuit path between the second terminal b and the fifth terminal e is disconnected, and two terminals of a second biasing unit formed by the fourth resistor R4 and the eighteenth resistor R18 connected in series are no longer short-circuited. Two terminals of a first biasing unit formed by the first resistor R1 and the seventeenth resistor R17 connected in series remain short-circuited by a conduction path of the first terminal a—the third terminal c—the sixth terminal f—the fourth terminal d. It should be noted that a conduction path of the first terminal a—the third terminal c—the sixth terminal f—the fifth terminal e also exists.

A conduction path of the second current-carrying wire 120—the tripping coil Lx—the fifth resistor R5—the fourth resistor R4—the eighteenth resistor R18—the sixth resistor R6—the first diode D1—the first current-carrying wire 110 is formed.

This turns on the second triode Q2, while the first triode Q1 remains off. A conduction path of the second current-carrying wire 120—the tripping coil Lx—the fifth resistor R 5—the second triode Q2—the seventh resistor R7—the first diode D1—the first current-carrying wire 110 is formed.

Accordingly, a voltage at the control electrode of the silicon controlled rectifier Q4 rises. During the negative half cycle of an AC power supply arrives, that is, when a level of the second current-carrying wire 120 is higher than a level of the first current-carrying wire 110, the silicon controlled rectifier Q4 is turned on, forming a high-current path of the second current-carrying wire 120—the tripping coil Lx—the silicon controlled rectifier Q4—the first diode D1—the first current-carrying wire 110.

The tripping coil Lx generates a strong electromagnetic force, thereby driving the tripping mechanism 230 to disconnect power connection between an input terminal and an output terminal of the power cord.

5. In a case that a connecting conductor between the third terminal c and the sixth terminal f is open-circuited.

A short-circuit path between the first terminal a and the fourth terminal d is disconnected, and two terminals of a first biasing unit formed by the first resistor R1 and the seventeenth resistor R17 connected in series are no longer short-circuited. A short-circuit path between the second terminal b and the fifth terminal e is disconnected, and two terminals of a second biasing unit formed by the fourth resistor R4 and the eighteenth resistor R18 connected in series are no longer short-circuited.

A conduction path of the second current-carrying wire 120—the tripping coil Lx—the second resistor R2—the first resistor R1—the seventeenth resistor R17—the third resistor R3—the first diode D1—the first current-carrying wire 110 is formed, and a conduction path of the second current-carrying wire 120—the tripping coil Lx—the fifth resistor R5—the fourth resistor R4—the eighteenth resistor R18—the sixth resistor R6—the first diode D1—the first current-carrying wire 110 is formed.

Both the first triode Q1 and the second triode Q2 are turned on. A conduction path of the second current-carrying wire 120—the tripping coil Lx—the second resistor R 2—the first triode Q1—the seventh resistor R7—the first diode D1—the first current-carrying wire 110 is formed, and a conduction path of the second current-carrying wire 120—the tripping coil Lx—the fifth resistor R5—the second triode Q2—the seventh resistor R7—the first diode D1—the first current-carrying wire 110 is formed.

Accordingly, a voltage at the control electrode of the silicon controlled rectifier Q4 rises. During the negative half cycle of an AC power supply, that is, when a level of the second current-carrying wire 120 is higher than a level of the first current-carrying wire 110, the silicon controlled rectifier Q4 is turned on, forming a high-current path of the second current-carrying wire 120—the tripping coil Lx—the silicon controlled rectifier Q4—the first diode D1—the first current-carrying wire 110.

The tripping coil Lx generates a strong electromagnetic force, thereby driving the tripping mechanism 230 to disconnect power connection between an input terminal and an output terminal of the power cord.

6. In a case that a portion of the second shielding conductor structure 140 between the fourth terminal d and the sixth terminal f is open-circuited.

A short-circuit path between the first terminal a and the fourth terminal d is disconnected, and two terminals of a first biasing unit formed by the first resistor R1 and the seventeenth resistor R17 connected in series are no longer short-circuited. Two terminals of a second biasing unit formed by the fourth resistor R4 and the eighteenth resistor R18 connected in series remain short-circuited by a conduction path of the second terminal b—the third terminal c—the sixth terminal f—the fifth terminal e. It should be noted that a conduction path of the first terminal a—the third terminal c—the sixth terminal f—the fifth terminal e also exists.

A conduction path of the second current-carrying wire 120—the tripping coil Lx—the second resistor R2—the first resistor R1—the seventeenth resistor R17—the third resistor R3—the first diode D1—the first current-carrying wire 110 is formed.

This turns on the first triode Q1, while the second triode Q2 remains off. A conduction path of the second current-carrying wire 120—the tripping coil Lx—the second resistor R2—the first triode Q1—the seventh resistor R7—the first diode D1—the first current-carrying wire 110 is formed.

Accordingly, a voltage at the control electrode of the silicon controlled rectifier Q4 rises. During the negative half cycle of an AC power supply, that is, when a level of the second current-carrying wire 120 is higher than a level of the first current-carrying wire 110, the silicon controlled rectifier Q4 is turned on, forming a high-current path of the second current-carrying wire 120—the tripping coil Lx—the silicon controlled rectifier Q4—the first diode D1—the first current-carrying wire 110.

The tripping coil Lx generates a strong electromagnetic force, thereby driving the tripping mechanism 230 to disconnect power connection between an input terminal and an output terminal of the power cord.

7. In a case that a portion of the second shielding conductor structure 140 between the fifth terminal e and the sixth terminal f is open-circuited.

A short-circuit path between the second terminal b and the fifth terminal e is disconnected, and two terminals of a second biasing unit formed by the fourth resistor R4 and the eighteenth resistor R18 connected in series are no longer short-circuited. Two terminals of a first biasing unit formed by the first resistor R1 and the seventeenth resistor R17 connected in series remain short-circuited by a conduction path of the first terminal a—the third terminal c—the sixth terminal f—the fourth terminal d. It should be noted that a conduction path of the second terminal b—the third terminal c—the sixth terminal f—the fourth terminal d also exists.

A conduction path of the second current-carrying wire 120—the tripping coil Lx—the fifth resistor R5—the fourth resistor R4—the eighteenth resistor R18—the sixth resistor R6—the first diode D1—the first current-carrying wire 110 is formed.

This turns on the second triode Q2, while the first triode Q1 remains off. A conduction path of the second current-carrying wire 120—the tripping coil Lx—the fifth resistor R5—the second triode Q2—the seventh resistor R7—the first diode D1—the first current-carrying wire 110 is formed.

Accordingly, a voltage at the control electrode of the silicon controlled rectifier Q4 rises. During the negative half cycle of an AC power supply arrives, that is, when a level of the second current-carrying wire 120 is higher than a level of the first current-carrying wire 110, the silicon controlled rectifier Q4 is turned on, forming a high-current path of the second current-carrying wire 120—the tripping coil Lx—the silicon controlled rectifier Q4—the first diode D1—the first current-carrying wire 110.

The tripping coil Lx generates a strong electromagnetic force, thereby driving the tripping mechanism 230 to disconnect power connection between an input terminal and an output terminal of the power cord.

8. In a case that the open-circuit detector 211 is operating normally and no open circuit occurs in the first shielding conductor structure 130 and the second shielding conductor structure 140.

Potentials of the first shielding conductor structure 130 and the second shielding conductor structure 140 are determined by voltage division across a first equivalent resistance (formed by the parallel combination of the second resistor R2 and the fifth resistor R5) and a second equivalent resistance (formed by the parallel combination of the third resistor R3 and the sixth resistor R6), and are maintained at a level insufficient to cause breakdown of the voltage stabilizing unit ZD1.

In this case, if the test switch TEST1 is pressed, this action effectively places the eighth resistor R8 in parallel with the second resistor R2 and the fifth resistor R5, thereby reducing the first equivalent resistance. This in turn increases the potentials of the first shielding conductor structure 130 and the second shielding conductor structure 140, causing the voltage stabilizing unit ZD1 to break down, and a conduction path of the second current-carrying wire 120—the tripping coil Lx—the test switch TEST1—the eighth resistor R8—the first shielding conductor structure 130/the second shielding conductor structure 140—the eleventh resistor R11—the voltage stabilizing unit ZD1—the tenth resistor R10—the seventh resistor R7—the first diode D1—the first current-carrying wire 110 is formed.

Accordingly, a voltage at the control electrode of the silicon controlled rectifier Q4 rises. During the negative half cycle of an AC power supply, that is, when a level of the second current-carrying wire 120 is higher than a level of the first current-carrying wire 110, the silicon controlled rectifier Q4 is turned on, forming a high-current path of the second current-carrying wire 120—the tripping coil Lx—the silicon controlled rectifier Q4—the first diode D1—the first current-carrying wire 110.

The tripping coil Lx generates a strong electromagnetic force, thereby driving the tripping mechanism 230 to disconnect power connection between an input terminal and an output terminal of the power cord.

9. In a case where a fault occurring in the open-circuit detector 211 (e.g., an open circuit or a short circuit in any individual component) causes a change in the potentials of the first shielding conductor structure 130 and the second shielding conductor structure 140, two possible situations may arise: in one situation, the potentials of the first shielding conductor structure 130 and the second shielding conductor structure 140 increase, directly causing the voltage stabilizing unit ZD1 to break down, resulting in tripping; and in another situation, the potentials of the first shielding conductor structure 130 and the second shielding conductor structure 140 decreases, so that when a user actively presses the test switch TEST1 for testing, tripping is not triggered.

The various possible faults of any individual component in the open-circuit detector 211 are listed below.

9.1. An open-circuit fault occurs in the second resistor R2 of the open-circuit detector 211: the first equivalent resistance increases, resulting in a decrease in the potentials of the first shielding conductor structure 130 and the second shielding conductor structure 140, and the voltage stabilizing unit ZD1 remains in a non-breakdown state.

It should be noted that, under this condition, the open-circuit detector 211 is unable to respond to an open-circuit condition of a portion of the first shielding conductor structure 130 between the first terminal a and the third terminal c to trigger tripping, but can still respond to and trigger tripping under the other four open-circuit conditions: an open-circuit in a portion of the first shielding conductor structure 130 between the second terminal b and the third terminal c, an open-circuit in a connecting conductor between the third terminal c and the sixth terminal f, an open-circuit in a portion of the second shielding conductor structure 140 between the fourth terminal d and the sixth terminal f, and an open-circuit in a portion of the second shielding conductor structure 140 between the fifth terminal e and the sixth terminal f.

It can be seen that in this case, if an open-circuit occurs in the portion of the first shielding conductor structure 130 between the first terminal a and the third terminal c, the user would be unable to discover it, posing a potential safety hazard.

9.2. An open-circuit fault occurs in the fifth resistor R5 of the open-circuit detector 211: the situation is similar to that when an open-circuit fault occurring in the second resistor R2 in 9.1.

9.3. An open-circuit fault occurs in the third resistor R3 of the open-circuit detector 211: the second equivalent resistance decreases, resulting in an increase in the potentials of the first shielding conductor structure 130 and the second shielding conductor structure 140, causing the voltage stabilizing unit ZD1 to break down and trigger tripping.

9.4. An open-circuit fault occurs in the sixth resistor R6 of the open-circuit detector 211: the situation is similar to that when an open-circuit fault occurring in the third resistor R3 in 9.3.

9.5. An open-circuit fault occurs in the first triode Q1 of the open-circuit detector 211: the open-circuit detector 211 is unable to respond to an open-circuit in a portion of the first shielding conductor structure 130 between the first terminal a and the third terminal c to trigger tripping.

It can be seen that in this case, if an open-circuit occurs in the portion of the first shielding conductor structure 130 between the first terminal a and the third terminal c, the user would be unable to discover it, posing a potential safety hazard.

9.6. An open-circuit fault occurs in the second triode Q2, the seventeenth resistor R17, or the eighteenth resistor R18 of the open-circuit detector 211: the situation is similar to that when an open-circuit fault occurring in the first triode Q1 in 9.5.

9.7. A short-circuit fault occurs in the second resistor R2 of the open-circuit detector 211: the fsirt equivalent resistance becomes zero, resulting in an increase in the potentials of the first shielding conductor structure 130 and the second shielding conductor structure 140, causing the voltage stabilizing unit ZD1 to break down and trigger tripping.

9.8. A short-circuit fault occurs in the fifth resistor R5 of the open-circuit detector 211: the situation is similar to that when a short-circuit fault occurs in the second resistor R2 in 9.7.

9.9. A short-circuit fault occurs in the third resistor R3 of the open-circuit detector 211: the second equivalent resistance becomes zero, resulting in a decrease in the potentials of the first shielding conductor structure 130 and the second shielding conductor structure 140, and the voltage stabilizing unit ZD1 remains in a non-breakdown state.

9.10. A short-circuit fault occurs in the sixth resistor R6 of the open-circuit detector 211: the situation is similar to that when a short-circuit fault occurs in the third resistor R3 in 9.9.

9.11. A short-circuit fault occurs in the first triode Q1 of the open-circuit detector 211: a voltage at the control electrode of the silicon controlled rectifier Q4 rises, triggering tripping.

9.12. A short-circuit fault occurs in the second triode Q2 of the open-circuit detector 211: the situation is similar to that when a short-circuit fault occurring in the first triode Q1 in 9.11.

For the foregoing various fault conditions of any individual component in the open-circuit detector 211, such as those in 9.3, 9.4, 9.7, 9.8, 9.11, and 9.12, tripping is directly triggered, preventing the user from continuing to use the power cord.

For the foregoing various fault conditions of any individual component in the open-circuit detector 211: such as those in 9.1, 9.2, 9.5, 9.6, 9.9, and 9.10, tripping is not triggered, and the user would be unable to discover the fault conditions, posing a potential safety hazard. Under these circumstances, if the user actively presses the test switch TEST1 to perform a test, since the potentials of the first shielding conductor structure 130 and the second shielding conductor structure 140 have already been altered, the potentials of the first shielding conductor structure 130 and the second shielding conductor structure 140 after pressing the test switch TEST1 will still be insufficiently high to cause the voltage stabilizing unit ZD1 to break down and trigger tripping. As a result, the user can intuitively and visually observe that tripping is not triggered after the test switch TEST1 is pressed, thereby enabling the user to determine that the detection-protection apparatus is abnormal and incapable of providing leakage protection or open-circuit protection for the shielding structures. Consequently, the user may cease using the faulty product, further enhancing safety assurance.

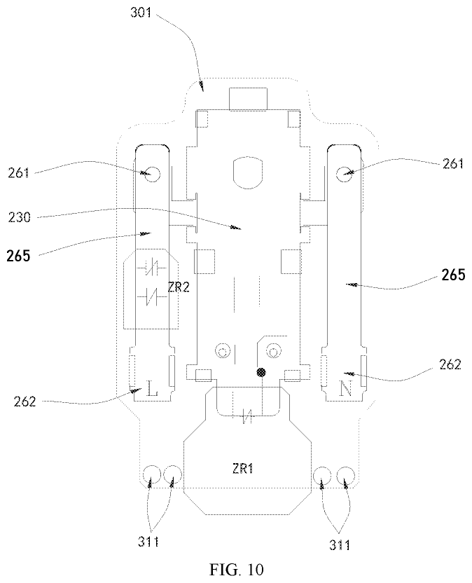

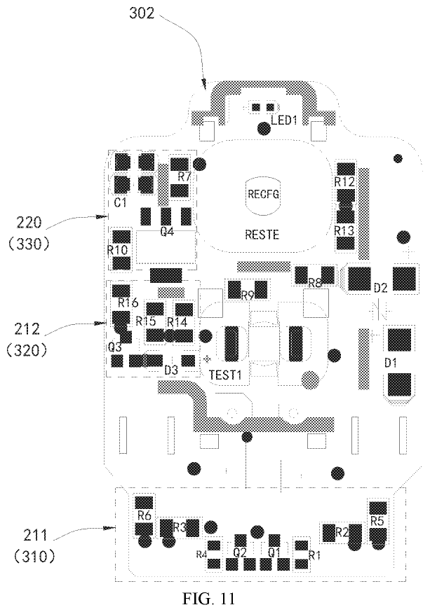

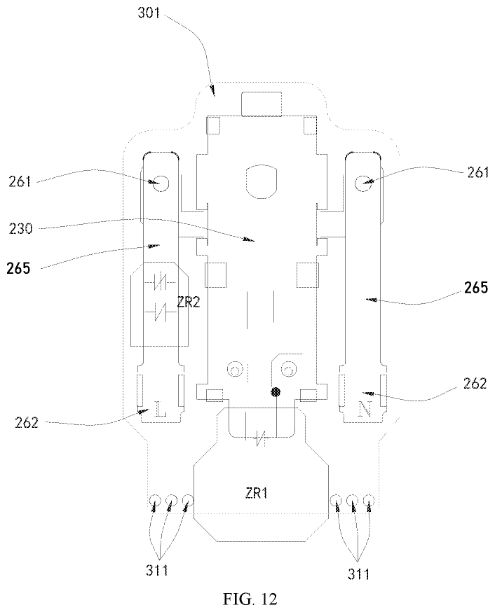

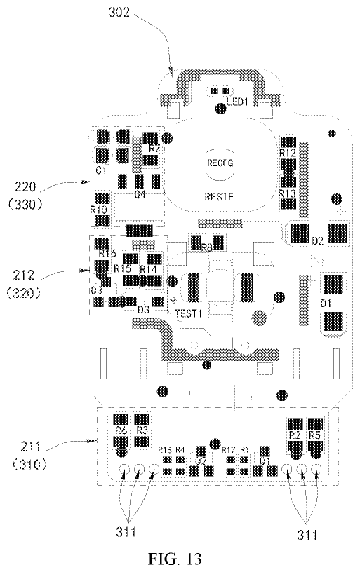

FIG. 10 is a schematic layout diagram of a first board surface of a circuit board of an electrical connection device according to an embodiment of the present disclosure. FIG. 11 is a schematic layout diagram of a second board surface of the circuit board of the electrical connection device according to the embodiment shown in FIG. 10 of the present disclosure. In addition, FIG. 12 is a schematic layout diagram of a first board surface of a circuit board of an electrical connection device according to another embodiment of the present disclosure; and FIG. 13 is a schematic layout diagram of a second board surface of the circuit board of the electrical connection device according to the embodiment shown in FIG. 12 of the present disclosure.

Referring to FIG. 10 to FIG. 13, in the circuit board of the electrical connection device according to the embodiments of the present disclosure, the circuit board located inside a housing 400 includes the first board surface 301 facing conductive pins 410 and a second board surface 302 facing away from the conductive pins 410. It can be understood that a shape of the circuit board is not limited to the shapes shown in FIG. 10 to FIG. 13, but may alternatively be an elliptical shape, a rectangular shape, a polygonal shape, or an irregular shape similar to the shapes shown in FIG. 10 to FIG. 13.

As described in FIG. 2 to FIG. 9 above, the detection-protection apparatus includes, in addition to the open-circuit detector 211, the leakage current detector 212, the driver 220, the tripping mechanism 230, and the tester 250 including the test switch TEST1, a reset button RESET. The reset button RESET includes a reconfiguration trigger lever RECFG that passes through the circuit board and is connected to the tripping mechanism 230.

As shown in FIG. 10 and FIG. 12, the tripping mechanism 230 is arranged in a central region of the first board surface 301; and the tripping mechanism 230 are provided with current-carrying conductors 265 at two sides for receiving electrical power through a press-contact with the conductive pins 410.

As shown in FIG. 11 and FIG. 13, the second board surface 302 is provided with a first region 310 located at an edge of the circuit board, and the open-circuit detector 211 is arranged in the first region 310.

As shown in FIG. 10, a shielding conductor solder joint 311 for soldered connection of the first shielding conductor structure 130 and/or the second shielding conductor structure 140 is provided at a position of the first board surface 301 corresponding to the first region 310. It should be noted that since the open-circuit detector 211 is arranged in the first region 310, i.e., the open-circuit detector 211 is arranged adjacent to the four shielding conductor solder joints 311, the open-circuit detector 211 can process electrical signals obtained from the four shielding conductor solder joints 311 and then output a signal to the driver 220. The electrical signals transmitted from the four shielding conductor solder joints 311 do not need to be transmitted over a long distance, simplifying circuit wiring/routing and enhancing anti-interference capability.

As shown in FIG. 11 and FIG. 13, the test switch TEST1 and the reset button RESET are arranged in a central region of the second board surface 302; and the leakage current detector 212 and the driver 220 are arranged in a region of the second board surface 302 adjacent to the test switch TEST1 and the reset button RESET.

According to the circuit board of the electrical connection device provided in the embodiments of the present disclosure, the first region 310 for connecting to the shielding conductor structure of the power cord 100 is arranged at the edge of the circuit board, that is, the shielding conductor solder joints 311 are located at the edge of the circuit board. This simplifies the soldering process between the first shielding conductor structure 130 and the second shielding conductor structure 140 and the circuit board, and also facilitates wire management. The open-circuit detector 211 is located in the first region 310, so that the circuit wiring between the shielding conductor solder joints 311 and the open-circuit detector 211 is relatively short, providing a strong anti-interference capability. This is particularly beneficial when there is a need for segmented detection of the first shielding conductor structure 130 and the second shielding conductor structure 140, as there will be multiple connection points between the open-circuit detector 211 and the first shielding conductor structure 130 and the second shielding conductor structure 140. The short distance between the shielding conductor solder joints 311 and the open-circuit detector 211 enables simpler circuit wiring. After handling an open-circuit in the first shielding conductor structure 130 and the second shielding conductor structure 140, the open-circuit detector 211 only needs to output a single open-circuit fault signal to the driver 220, eliminating the need for a plurality of long circuit traces from the first region 310 to the driver 220. In the circuit layout of this embodiment, given that the tripping mechanism 230, the test switch TEST1, and the reset button RESET occupy the main positions of the circuit board, limited board surface space of the circuit board is reasonably allocated to dispose the open-circuit detector 211, the leakage current detector 212, and the driver 220, which not only simplifies wiring and enhances an anti-interference capability but also minimizes a circuit board size.

Referring to FIG. 11 and FIG. 13, in the circuit board provided in some embodiments of the present disclosure, the reset button RESET, the test switch TEST1, and the first region 310 are sequentially arranged along a longitudinal axis of the second board surface 302.

It can be understood that, taking the orientation of the circuit board shown in FIG. 11 or FIG. 13 as an example, a vertical direction in the figures corresponds to the longitudinal direction of the second board surface 302. The test switch TEST1 is arranged at the central position in the vertical direction of the second board surface 302, the reset button RESET is arranged above the test switch TEST1, and the first region 310 is located below the test switch TEST1.

Referring to FIG. 11 and FIG. 13, in the circuit board provided in some embodiments of the present disclosure, the leakage current detector 212 is located in a region to the left of the test switch TEST1, and the driver 220 is located in a region to the left of the reset button RESET and adjacent to the leakage current detector 212. The leakage current detector 212 is arranged adjacent to the test switch TEST1, so that when the test switch TEST1 of the tester 250 is pressed, a transmission path of a simulated leakage signal on the first shielding conductor structure 130 and the second shielding conductor structure 140 is shorter, facilitating wiring; and the driver 220 is arranged adjacent to the leakage current detector 212, so that a leakage fault signal output by the leakage current detector 212 is transmitted to the driver 220 via a shorter path, facilitating wiring.

It can be understood that because the test switch TEST1 and the reset button RESET are both located in the central region in the vertical direction, the leakage current detector 212 may alternatively be arranged in a region to the right of the test switch TEST1, and correspondingly, the driver 220 may alternatively be arranged in a region to the right of the reset button RESET and adjacent to the leakage current detector 212.

Referring to FIG. 10 and FIG. 12, in the circuit board provided in some embodiments of the present disclosure, the current-carrying conductor 265 extends along a longitudinal axis of the first board surface 301. The current-carrying conductor 265 has an end portion distant from the shielding conductor solder joint 311, which serves as a power contact terminal 261 for press-contact with the conductive pins 410, and an end portion proximate to the shielding conductor solder joint 311, which serves as a power output solder joint 262 for soldering the first current-carrying wire 110 or the second current-carrying wire 120.

It can be understood that the tripping mechanism 230 is located in the central region of the first board surface 301, and the two current-carrying conductors 265 are respectively located at two sides of the tripping mechanism 230. This ensures balanced force application when the tripping mechanism 230 operates to cause displacement or deformation of the two current-carrying conductors 265. In addition, relatively large components such as the tripping mechanism 230 and the current-carrying conductors 265 are arranged at the first board surface 301 of the circuit board, while other smaller components of the detection-protection apparatus that require electrical connection through printed circuits on the circuit board are arranged at the second board surface 302. This enables better wiring and simplifies circuit routing. In addition, the power output solder point 262 is located proximate to the first region 310, so that the first current-carrying wire 110 and the second current-carrying wire 120 do not need to extend too far on the circuit board when soldered to the current-carrying conductors 265.

It should be noted that when the reconfiguration trigger lever RECFG of the reset button RESET is pressed, the power contact terminal 261 of the current-carrying conductor 265 contacts and presses against the conductive pins 410, thereby enabling an accessible connection to a mains supply.

In the circuit board provided in some embodiments of the present disclosure, the first shielding conductor structure 130 has a first terminal a proximate to the circuit board, a second terminal b distant from the first terminal a, and a third terminal c between the first terminal a and the second terminal b; the second shielding conductor structure 140 has a fourth terminal d proximate to the circuit board, a fifth terminal e distant from the fourth terminal d, and a sixth terminal f between the fourth terminal d and the fifth terminal e; the third terminal c is connected to the sixth terminal f; and referring to FIG. 10, the first region 310 includes four shielding conductor solder joints 311, each connected to a corresponding one of the first terminal a, the second terminal b, the fourth terminal d, and the fifth terminal e.

It can be understood that because the open-circuit detector 211 is respectively connected to the first terminal a, the second terminal b, the fourth terminal d, and the sixth terminal f, the first region 310 is provided with four shielding conductor solder joints 311 for respective connection to the first terminal a, the second terminal b, the fourth terminal d, and the fifth terminal e, as shown for example in FIG. 10. After the first terminal a, the second terminal b, the fourth terminal d, and the fifth terminal e are connected to the four shielding conductor solder joints 311 in the first region 310, they are electrically connected to the open-circuit detector 211 through traces on the circuit board.

In some other embodiments of the present disclosure, the circuit board further includes two shielding conductor solder joints 311 in the first region 310 for respective connection to the third terminal c and the sixth terminal f. That is, the first region 310 is provided with a total of six shielding conductor solder joints 311 for respectively connecting to the first terminal a, the second terminal b, the third terminal c, the fourth terminal d, the fifth terminal e, and the sixth terminal f. Referring to FIG. 12 and FIG. 13, specifically, three shielding conductor solder joints 311 are arranged at each of a lower left corner and a lower right corner of the first region 310.

Because the third terminal c and the sixth terminal f need to be electrically connected, to ensure a reliable electrical connection between the third terminal c and the sixth terminal f, two additional shielding conductor solder joints 311 are provided in the first region 310, allowing the third terminal c and the sixth terminal f to be routed to the circuit board and electrically connected through the circuit board.

Referring to FIG. 2 to FIG. 7, in some embodiments of the present disclosure, the open-circuit detector 211 on the circuit board includes a first switch 201 and a second switch 202; the first switch 201 includes a first triode Q1 and a first resistor R1 for providing a turn-on voltage to the first triode Q1; and the second switch 202 includes a second triode Q2 and a fourth resistor R4 for providing a turn-on voltage to the second triode Q2. Further, the first switch 201 further includes a second resistor R2 and a third resistor R3, one terminal of the second resistor R2 is connected to the second current-carrying wire 120, the other terminal of the second resistor R2 is connected to one terminal of the first resistor R1 and an emitter of the first triode Q1, the other terminal of the first resistor R1 is connected to a base of the first triode Q1 and one terminal of the third resistor R3, and the other terminal of the third resistor R3 is connected to the first current-carrying wire 110; the second switch 202 further includes a fifth resistor R5 and a sixth resistor R6, one terminal of the fifth resistor R5 is connected to the second current-carrying wire 120, the other terminal of the fifth resistor R5 is connected to one terminal of the fourth resistor R4 and an emitter of the second triode Q2, the other terminal of the fourth resistor R4 is connected to a base of the second triode Q2 and one terminal of the sixth resistor R6, and the other terminal of the sixth resistor R6 is connected to the first current-carrying wire 110; and a collector of the first triode Q1 and a collector of the second triode Q2 are connected to the driver 220. Referring to FIG. 8 and FIG. 9, in some embodiments of the present disclosure, the open-circuit detector on the circuit board includes a first switch 201 and a second switch 202; the first switch 201 includes a first triode Q1 and a first voltage dividing unit; the second switch 202 includes a second triode Q2 and a second voltage dividing unit; the first voltage dividing unit includes a second resistor R2, a first resistor R1, a seventeenth resistor R17, and a third resistor R3 connected in series in sequence, and the second voltage dividing unit includes a fifth resistor R5, a fourth resistor R4, an eighteenth resistor R18, and a sixth resistor R6 connected in series in sequence; a connection point between the second resistor R2 and the first resistor R1 is connected to the shielding conductor solder joint corresponding to the first terminal a and an emitter of the first triode Q1; a connection point between the first resistor R1 and the seventeenth resistor R17 is connected to a base of the first triode Q1; a connection point between the seventeenth resistor R17 and the third resistor R3 is connected to the shielding conductor solder joint corresponding to the fourth terminal d; a connection point between the fifth resistor R5 and the fourth resistor R4 is connected to the shielding conductor solder joint corresponding to the second terminal b and an emitter of the second triode Q2; a connection point between the fourth resistor R4 and the eighteenth resistor R18 is connected to a base of the second triode Q2; a connection point between the eighteenth resistor R18 and the sixth resistor R6 is connected to the shielding conductor solder joint corresponding to the fifth terminal e; the second resistor R2 and the fifth resistor R5 are connected together and connected to the second current-carrying wire 120, and the third resistor R3 and the sixth resistor R6 are connected together and connected to the first current-carrying wire 110; and a collector of the first triode Q1 and a collector of the second triode Q2 are connected to the driver 220. It should be noted that the terminal of the second resistor R2 connected to the second current-carrying wire 120 may be directly connected to the second current-carrying wire 120, or may be indirectly connected to the second current-carrying wire 120 via the tripping coil Lx as shown in FIG. 2 to FIG. 9. Similarly, the terminal of the fifth resistor R5 connected to the second current-carrying wire 120 may be directly connected to the second current-carrying wire 120, or may be indirectly connected to the second current-carrying wire 120 via the tripping coil Lx as shown in FIG. 2 to FIG. 5. In addition, the terminal of the third resistor R3 connected to the first current-carrying wire 110 may be directly connected to the first current-carrying wire 110, or may be indirectly connected to the first current-carrying wire 110 via the first diode D1 as shown in FIG. 2 to FIG. 9. Similarly, the terminal of the sixth resistor R6 connected to the first current-carrying wire 110 may be directly connected to the first current-carrying wire 110, or may be indirectly connected to the first current-carrying wire 110 via the first diode D1 as shown in FIG. 2 to FIG. 9.

Referring to FIG. 11, in the embodiments shown in FIG. 2 to FIG. 7, the first triode Q1, the second triode Q2, the first resistor R1, the second resistor R2, the third resistor R3, the fourth resistor R4, the fifth resistor R5, and the sixth resistor R6 are all arranged in the first region 310. Referring to FIG. 13, in the embodiments shown in FIG. 8 to FIG. 9, the first triode Q1, the second triode Q2, the first resistor R1, the second resistor R2, the third resistor R3, the fourth resistor R4, the fifth resistor R5, the sixth resistor R6, the seventeenth resistor R17, and the eighteenth resistor R18 are all arranged in the first region 310.

It can be understood that, to detect open-circuit conditions of the first shielding conductor structure 130 and the second shielding conductor structure 140, the open-circuit detector 211 is configured with a considerable number of triode components and resistor components, and the connection relationships are complex. Therefore, all components of the open-circuit detector 211 are arranged in the first region 310, enabling electrical connections to the shielding conductor solder joints 311 via shorter traces. Centrally disposing the components included in the open-circuit detector 211 in one region also helps to reduce a layout size required on the circuit board.

Referring to FIG. 5 to FIG. 7, in some embodiments of the present disclosure, the leakage current detector 212 on the circuit board includes a fourteenth resistor R14, a fifteenth resistor R15, a sixteenth resistor R16, and a third triode Q3, one terminal of the fourteenth resistor R14 is connected to the second current-carrying wire 120, the other terminal of the fourteenth resistor R14 is connected to one terminal of the fifteenth resistor R15 and a base of the third triode Q3, an emitter of the third triode Q3 is connected to any one of the shielding conductor solder joints 311, the other terminal of the fifteenth resistor R15 is connected to the first current-carrying wire 110, a collector of the third triode Q3 is connected to one terminal of the sixteenth resistor R16, and the other terminal of the sixteenth resistor R16 is connected to the driver 220. In addition, referring to FIG. 9, in some embodiments of the present disclosure, the leakage current detector 212 on the circuit board includes a fourteenth resistor R14, a fifteenth resistor R15, a third triode Q3, and a third diode D3, one terminal of the fourteenth resistor R14 is connected to the second current-carrying wire 120, the other terminal of the fourteenth resistor R14 is connected to one terminal of the fifteenth resistor R15 and a base of the third triode Q3, an emitter of the third triode Q3 is connected to a cathode of the third diode D3, an anode of the third diode D3 is connected to the shielding conductor solder joint corresponding to the sixth terminal f, the other terminal of the fifteenth resistor R15 is connected to the first current-carrying wire 110, and a collector of the third triode Q3 is connected to the driver 220. It should be noted that the terminal of the fourteenth resistor R14 connected to the second current-carrying wire 120 may be directly connected to the second current-carrying wire 120, or may be indirectly connected to the second current-carrying wire 120 via the tripping coil Lx as shown in FIG. 5 to FIG. 7 and FIG. 9. The terminal of the fifteenth resistor R15 connected to the first current-carrying wire 110 may be directly connected to the first current-carrying wire 110, or may be indirectly connected to the first current-carrying wire 110 via the first diode D1 as shown in FIG. 5 to FIG. 7 and FIG. 9. Referring to FIG. 11, in the embodiments shown in FIG. 5 to FIG. 7, the fourteenth resistor R14, the fifteenth resistor R15, the sixteenth resistor R16, and the third triode Q3 are all arranged in a second region 320 to the left of the test switch TEST1 on the second board surface 302. Referring to FIG. 13, in the embodiments shown in FIG. 7 to FIG. 9, the fourteenth resistor R14, the fifteenth resistor R15, the third triode Q3, and the third diode D3 are all arranged in a second region 320 to the left of the test switch TEST1 on the second board surface 302.

It can be understood that the leakage current detector 212 detects leakage conditions of the first shielding conductor structure 130 and the second shielding conductor structure 140 by using a triode component in combination with a plurality of resistor components. Centrally disposing the components included in the leakage current detector 212 in the second region 320 to the left of the test switch TEST1 helps to reduce a layout size required for the leakage current detector 212 on the circuit board.

Referring to FIG. 2 to FIG. 4, in some embodiments of the present disclosure, the leakage current detector 212 on the circuit board includes an eleventh resistor R11 and a voltage stabilizing unit ZD1, an anode of the voltage stabilizing unit ZD1 is connected to the driver 220, a cathode of the voltage stabilizing unit ZD1 is connected to one terminal of the eleventh resistor R11, and the other terminal of the eleventh resistor R11 is connected to any one of the shielding conductor solder joints 311; and the eleventh resistor R11 and the voltage stabilizing unit ZD1 are both arranged in the second region 320 to the left of the test switch TEST1 on the second board surface 302. In addition, referring to FIG. 8, in some embodiments of the present disclosure, the leakage current detector 212 on the circuit board includes an eleventh resistor R11 and a voltage stabilizing unit ZD1, an anode of the voltage stabilizing unit ZD1 is connected to the driver 220, a cathode of the voltage stabilizing unit ZD1 is connected to one terminal of the eleventh resistor R11, and the other terminal of the eleventh resistor R11 is connected to the shielding conductor solder joint corresponding to the sixth terminal f; and the eleventh resistor R11 and the voltage stabilizing unit ZD1 are both arranged in the second region 320 to the left of the test switch TEST1 on the second board surface 302.

It can be understood that the leakage current detector 212 detects leakage conditions of the first shielding conductor structure 130 and the second shielding conductor structure 140 by using the voltage stabilizing unit ZD1 in combination with a resistor component. Centrally disposing the components included in the leakage current detector 212 in the second region 320 to the left of the test switch TEST1 helps to reduce a layout size required for the leakage current detector 212 on the circuit board.

Referring to FIG. 2 to FIG. 7, in some embodiments of the present disclosure, the driver 220 on the circuit board includes a silicon controlled rectifier Q4, a seventh resistor R7, a tenth resistor R10, and a first capacitor C1, the detection-protection apparatus further includes a tripping coil Lx, the second current-carrying wire 120 is connected to one terminal of the tripping coil Lx, the other terminal of the tripping coil Lx is connected to an anode of the silicon controlled rectifier Q4, a control electrode of the silicon controlled rectifier Q4 is connected to one terminal of the seventh resistor R7, one terminal of the tenth resistor R10, one terminal of the first capacitor C1, and the leakage current detector 212, the other terminal of the tenth resistor R10 is connected to the open-circuit detector 211, and a cathode of the silicon controlled rectifier Q4, the other terminal of the first capacitor C1, and the other terminal of the seventh resistor R7 are all connected to the first current-carrying wire 110. It should be noted that the cathode of the silicon controlled rectifier Q4, the terminal of the first capacitor C1 connected to the first current-carrying wire 110, and the terminal of the seventh resistor R7 connected to the first current-carrying wire 110 may be directly connected to the first current-carrying wire 110, or may be indirectly connected to the first current-carrying wire 110 via the first diode D1 as shown in FIG. 5 to FIG. 7. Referring to FIG. 11 and FIG. 13, the silicon controlled rectifier Q4, the seventh resistor R7, the tenth resistor R10, and the first capacitor C1 are all arranged in a third region 330 to the left of the reset button RESET on the second board surface 302.

It can be understood that, to respond to the open-circuit fault signal output by the open-circuit detector 211 and the leakage fault signal transmitted from the leakage current detector 212, the driver 220 employs a silicon controlled rectifier device, a capacitor, and a plurality of resistor components. Centrally disposing the components included in the driver 220 in the third region 330 to the left of the reset button RESET helps to reduce a layout size required for the driver 220 on the circuit board.

In addition, referring to FIG. 8 and FIG. 9, in some embodiments of the present disclosure, the tester 250 on the circuit board further includes an eighth resistor R8, one terminal of the test switch TEST1 is connected to a connection point between the second resistor R2 and the fifth resistor R5, the other terminal of the test switch TEST1 is connected to one terminal of the eighth resistor R8, and the other terminal of the eighth resistor R8 is connected to the shielding conductor solder joint corresponding to the third terminal c. Referring to FIG. 13, the eighth resistor R8 is arranged in the central region of the second board surface 302 and arranged adjacent to the test switch TEST1.

In the circuit board provided in some embodiments of the present disclosure, the circuit board has a length dimension in a range of 56 mm±10 mm and a width dimension in a range of 36 mm'510 mm; the first region 310 has a length dimension in a range of 30 mm±3 mm and a width dimension in a range of 8.5 mm±10 mm; a region occupied by the leakage current detector 212 on the second board surface 302 has a length dimension in a range of 10 mm±3 mm and a width dimension in a range of 8 mm±3 mm; and a region occupied by the driver 220 on the second board surface 302 has a length dimension in a range of 15 mm±3 mm and a width dimension in a range of 10 mm±3 mm.

It can be understood that the detection-protection apparatus shown in FIG. 2 to FIG. 9 requires a relatively large quantity of switch components, diode components, resistor components, capacitor components, and the like to detect a leakage condition and an open-circuit condition of the shielding conductor structure of the power cord. According to the circuit board provided in the embodiments of the present disclosure, based on the tripping mechanism 230, the test switch TEST1, and the reset button RESET occupying main positions of the circuit board, limited board surface space of the circuit board is reasonably allocated to dispose the open-circuit detector 211, the leakage current detector 212, and the driver 220, which not only simplifies wiring and enhances an anti-interference capability but also minimizes a circuit board size.

Referring to FIG. 10, in the circuit board provided in some embodiments of the present disclosure, the first varistor ZR1 in the Surge Protective Device 270 is arranged in the central region of the first board surface 301 at a position corresponding to the first region 310, and the first varistor ZR1 are respectively provided with two shielding conductor solder joints 311 at two sides. Referring to FIG. 12, two sides of the first varistor ZR1 are respectively provided with three shielding conductor solder joints 311.

It can be understood that the first varistor ZR1 in the Surge Protective Device 270 is relatively large in size. Arranging it in the central region of the position on the first board surface 301 corresponding to the first region 310 divides the four shielding conductor solder joints 311 into two groups, avoiding difficulties in soldering caused by all four shielding conductor solder joints 311 being concentrated in a very small area.

In addition, referring to FIG. 10 and FIG. 12, the second varistor ZR2 is arranged in a region to the left of the tripping mechanism 230 on the first board surface 301. Referring to FIG. 11 and FIG. 13, a freewheeling module including the first diode D1 and the second diode D2 in the detection-protection apparatus is arranged in a region to the right of the tester 250 on the second board surface 302. In addition, referring to FIG. 11 and FIG. 13, a solder joint for the tripping coil Lx may be further arranged below the tester 250 on the second board surface 302.

It should be noted that in FIG. 10 to FIG. 13 of the present disclosure, the arrangement positions of the components in various modules may be interchanged, and FIG. 10 to FIG. 13 only illustrate one form of layout.

According to the circuit board of some embodiments of the present disclosure, components in the open-circuit detector 211, the leakage current detector 212, the driver 220, and the tripping mechanism 230 are packaged using surface-mount technology or through-hole technology.

According to the circuit board of some embodiments of the present disclosure, the circuit board employs a wiring configuration of a single-layer board, a double-layer board, or a multi-layer board.

According to the circuit board of some embodiments of the present disclosure, the circuit board is processed by wave soldering, reflow soldering, or manual soldering.

In addition, in accordance with a second aspect of the present disclosure, an embodiment provides an electrical connection device, including the circuit board according to the embodiments of the first aspect, a power cord 100, a detection-protection apparatus arranged at the circuit board and connected to the power cord 100, and a housing 400 enclosing the circuit board, where the housing 400 is provided with conductive pins 410 for accessing a power supply.

According to the electrical connection device of some embodiments of the present disclosure, a wire clamp for clamping the power cord 100 is provided at a connection between the housing 400 and the power cord 100.

It can be understood that by providing the wire clamp to fix the power cord 100, it is possible to prevent the various ports connected to the detection-protection apparatus from easily detaching due to external pulling forces on the power cord 100.

The first shielding conductor structure 130 has a first terminal a proximate to the circuit board, a second terminal b distant from the first terminal a, and a third terminal c between the first terminal a and the second terminal b; and the second shielding conductor structure 140 has a fourth terminal d proximate to the circuit board, a fifth terminal e distant from the fourth terminal d, and a sixth terminal f between the fourth terminal d and the fifth terminal e.

The third terminal c and the sixth terminal f are electrically connected by one of the following three manners:
manner 1: soldered connection at the wire clamp;
manner 2: soldered connection inside the housing 400; and
manner 3: routing to the shielding conductor solder joint 311 to achieve electrical connection through the circuit board.

It can be understood that the connection position between the third terminal c of the first shielding conductor structure 130 and the sixth terminal f of the second shielding conductor structure 140 may be flexibly arranged at different positions according to actual cases. For example, when the connection is arranged at the wire clamp as in the manner 1, the wire clamp can clamp a soldered portion between the third terminal c and the sixth terminal f while clamping the power cord 100, preventing the soldered portion from becoming loose or detached. When the connection is arranged inside the housing 400 as in the manner 2, the soldered connection between the third terminal c and the sixth terminal f has larger space, making operation convenient. When the connection is routed to the shielding conductor solder joints 311 as in the manner 3, the third terminal c and the sixth terminal f are soldered and connected to the circuit board together with the first terminal a, the second terminal b, the fourth terminal d, and the fifth terminal e, so that the connection between the circuit board and the first shielding conductor structure 130 and the second shielding conductor structure 140 is more stable and reliable. Moreover, the electrical connection between the third terminal c and the sixth terminal f through the circuit board is also more reliable, and such connection is less likely to become disconnected.

Although embodiments of the present disclosure are described in detail above with reference to the accompanying drawings, the present disclosure is not limited to the foregoing embodiments, and various changes can be made within the knowledge scope of a person of ordinary skill in the art without departing from the principle of the present disclosure.

What is claimed is:

1. A circuit board of an electrical connection device, wherein the electrical connection device comprises:
a power cord, including a first current-carrying wire, a second current-carrying wire, a first shielding conductor structure wrapping the first current-carrying wire, and a second shielding conductor structure wrapping the second current-carrying wire;
a detection-protection apparatus arranged at the circuit board and connected to the power cord, the detection-protection apparatus including an open-circuit detector, a leakage current detector, a driver, a tripping mechanism, a tester including a test switch, and a reset button; and
a housing enclosing the circuit board, the housing arranged with conductive pins for accessing a power supply;
the circuit board includes a first board surface facing the conductive pins and a second board surface facing away from the conductive pins;
the tripping mechanism is arranged in a central region of the first board surface with current-carrying conductors at two sides of the tripping mechanism for receiving electrical power through a press-contact with the conductive pins;
the second board surface includes a first region located at an edge of the circuit board where the open-circuit detector is arranged, and the first board surface is arranged with a shielding conductor solder joint for soldered connection of the first shielding conductor structure and/or the second shielding conductor structure, the shielding conductor solder joint being located corresponding to the first region; and
the test switch and the reset button are arranged in a central region of the second board surface, and the leakage current detector and the driver are arranged in a region of the second board surface adjacent to the test switch and the reset button.

2. The circuit board of claim 1, wherein the reset button, the test switch, and the first region are arranged in sequence along a longitudinal axis of the second board surface.

3. The circuit board of claim 2, wherein:
the leakage current detector is located in a region to the left of the test switch, and the driver is located in a region to the left of the reset button and adjacent to the leakage current detector; or
the leakage current detector is located in a region to the right of the test switch, and the driver is located in a region to the right of the reset button and adjacent to the leakage current detector.

4. The circuit board of claim 2, wherein the current-carrying conductor, which extends along a longitudinal axis of the first board surface, has an end portion distant from the shielding conductor solder joint and serving as a power contact terminal for press-contact with the conductive pins, and another end portion proximate to the shielding conductor solder joint and serving as a power output solder joint for soldering the first current-carrying wire or the second current-carrying wire.

5. The circuit board of claim 2, wherein the leakage current detector includes a fourteenth resistor, a fifteenth resistor, a sixteenth resistor, and a third triode,
the fourteenth resistor having a terminal connected to the second current-carrying wire and another terminal connected to a base of the third triode,
the fifteenth resistor having a terminal connected to another terminal of the fourteenth resistor and another terminal connected to the first current-carrying wire,
the sixteenth resistor having a terminal connected a collector of the third triode and another terminal connected to the driver,
the third triode having an emitter connected to any one of the shielding conductor solder joints; and
the fourteenth resistor, the fifteenth resistor, the sixteenth resistor, and the third triode are all arranged in a second region to the left of the test switch on the second board surface.

6. The circuit board of claim 2, wherein the leakage current detector includes an eleventh resistor and a voltage stabilizing unit,
the voltage stabilizing unit having an anode connected to the driver and a cathode connected to one terminal of the eleventh resistor, and the other terminal of the eleventh resistor being connected to any one of the shielding conductor solder joints; and
the eleventh resistor and the voltage stabilizing unit are both arranged in a second region to the left of the test switch on the second board surface.

7. The circuit board of claim 2, wherein the driver includes a silicon controlled rectifier, a seventh resistor, a tenth resistor, and a first capacitor,
the silicon controlled rectifier having a control electrode connected to the leakage current detector and a cathode connected to the first current carrying line,
the detection-protection apparatus further comprises a tripping coil having a terminal connected to the second current-carrying wire and another terminal connected to an anode of the silicon controlled rectifier,
the seventh resistor having a terminal connected to the control electrode of the silicon controlled rectifier and another terminal connected to the first current-carrying wire,
the tenth resistor having a terminal connected to the control electrode of the silicon controlled rectifier and another terminal connected to the open-circuit detector,
the first capacitor having a terminal connected to the control electrode of the silicon controlled rectifier and another terminal connected to the first current-carrying wire; and
the silicon controlled rectifier, the seventh resistor, the tenth resistor, and the first capacitor are all arranged in a third region to the left of the reset button on the second board surface.

8. The circuit board of claim 1, wherein the first shielding conductor structure has a first terminal proximate to the circuit board, a second terminal distant from the first terminal, and a third terminal between the first terminal and the second terminal;
the second shielding conductor structure has a fourth terminal proximate to the circuit board, a fifth terminal distant from the fourth terminal, and a sixth terminal between the fourth terminal and the fifth terminal;
the third terminal is connected to the sixth terminal; and
the first region is arranged with four shielding conductor solder joints, each connected to a corresponding one of the first terminal, the second terminal, the fourth terminal, and the fifth terminal.

9. The circuit board of claim 8, wherein the first region is further arranged with two shielding conductor solder joints for respective connection to the third terminal and the sixth terminal.

10. The circuit board of claim 9, wherein:
the open-circuit detector includes:
a first switch including a first triode and a first voltage dividing unit, the first voltage dividing unit including a second resistor, a first resistor, a seventeenth resistor, and a third resistor connected in series in sequence; and
a second switch including a second triode and a second voltage dividing unit, the second voltage dividing unit including a fifth resistor, a fourth resistor, an eighteenth resistor, and a sixth resistor connected in series in sequence;
a connection point between the second resistor and the first resistor is connected to the shielding conductor solder joint corresponding to the first terminal and an emitter of the first triode;
a connection point between the first resistor and the seventeenth resistor is connected to a base of the first triode;
a connection point between the seventeenth resistor and the third resistor is connected to the shielding conductor solder joint corresponding to the fourth terminal;
a connection point between the fifth resistor and the fourth resistor is connected to the shielding conductor solder joint corresponding to the second terminal and an emitter of the second triode;
a connection point between the fourth resistor and the eighteenth resistor is connected to a base of the second triode;
a connection point between the eighteenth resistor and the sixth resistor is connected to the shielding conductor solder joint corresponding to the fifth terminal;
the second resistor and the fifth resistor are connected together and connected to the second current-carrying wire, and the third resistor and the sixth resistor are connected together and connected to the first current-carrying wire;
each of the first triode and the second triode has a collector connected to the driver; and
the first triode, the second triode, the first resistor, the second resistor, the third resistor, the fourth resistor, the fifth resistor, the sixth resistor, the seventeenth resistor, and the eighteenth resistor are all arranged in the first region.

11. The circuit board of claim 10, wherein the leakage current detector includes a fourteenth resistor, a fifteenth resistor a third triode and a third diode,
the fourteenth resistor having a terminal connected to the second current-carrying wire and another terminal connected to a base of the third triode,
the fifteenth resistor having a terminal connected to another terminal of the fourteenth resistor and another terminal connected to the first current-carrying wire,
the third diode having a cathode connected to an emitter of the third triode and an anode connected to the shielding conductor solder joint corresponding to the sixth terminal, and
the third triode having a collector connected to the driver; and
the fourteenth resistor, the fifteenth resistor, the third triode, and the third diode are all arranged in a second region to the left of the test switch on the second board surface.

12. The circuit board of claim 11, wherein the tester further includes an eighth resistor having a terminal connected to one terminal of the test switch and another terminal connected to the shielding conductor solder joint corresponding to the third terminal, and the other terminal of the test switch being connected to a connection point between the second resistor and the fifth resistor, and
the eighth resistor is arranged in the central region of the second board surface and arranged adjacent to the test switch.

13. The circuit board of claim 10, wherein the leakage current detector includes an eleventh resistor and a voltage stabilizing unit,
the voltage stabilizing unit having an anode connected to the driver and a cathode connected to one terminal of the eleventh resistor, and the other terminal of the eleventh resistor being connected to the shielding conductor solder joint corresponding to the sixth terminal; and
the eleventh resistor and the voltage stabilizing unit are both arranged in a second region to the left of the test switch on the second board surface.

14. The circuit board of claim 1,
wherein the open-circuit detector includes a first switch and a second switch, the first switch including a first triode and a first resistor for providing a turn-on voltage to the first triode, and the second switch having a second triode and a fourth resistor for providing a turn-on voltage to the second triode; and
wherein:
two terminals of the first resistor are respectively electrically connected to the shielding conductor solder joints corresponding to the first terminal and the fourth terminal, and two terminals the fourth resistor are respectively electrically connected to the shielding conductor solder joints corresponding to the second terminal and the fifth terminal; or
the two terminals of the first resistor are respectively electrically connected to the shielding conductor solder joints corresponding to the first terminal and the fifth terminal, and the two terminals of the fourth resistor are respectively electrically connected to the shielding conductor solder joints corresponding to the second terminal and the fourth terminal.

15. The circuit board of claim 14, wherein:
the first switch further includes:
a second resistor having a terminal connected to the second current-carrying wire, and another terminal connected to one terminal of the first resistor and an emitter of the first triode, the other terminal of the first resistor being connected to a base of the first triode, and
a third resistor having a terminal connected to the other terminal of the first resistor, and another terminal connected to the first current-carrying wire;
the second switch further includes:
a fifth resistor having a terminal connected to the second current-carrying wire, and another terminal connected to one terminal of the fourth resistor and an emitter of the second triode, the other terminal of the fourth resistor being connected to a base of the second triode, and
a sixth resistor having a terminal connected to the other terminal of the fourth resistor, and another terminal connected to the first current-carrying wire;
each of the first triode and the second triode includes a collector connected to the driver;
and the first triode, the second triode, the first resistor, the second resistor, the third resistor, the fourth resistor, the fifth resistor, and the sixth resistor are all arranged in the first region.

16. The circuit board of claim 1, wherein:
the circuit board has a length dimension in a range of 56 mm±10 mm and a width dimension in a range of 36 mm±10 mm;
the first region has a length dimension in a range of 30 mm±3 mm and a width dimension in a range of 8.5 mm±10 mm;
a region occupied by the leakage current detector on the second board surface has a length dimension in a range of 10 mm±3 mm and a width dimension in a range of 8 mm±3 mm; and
a region occupied by the driver on the second board surface has a length dimension in a range of 15 mm±3 mm and a width dimension in a range of 10 mm±3 mm.

17. The circuit board of claim 1, wherein components in the open-circuit detector, the leakage current detector, the driver, and the tripping mechanism are packaged using surface-mount technology or through-hole technology.

18. The circuit board of claim 1, wherein the circuit board employs a wiring configuration of a single-layer board, a double-layer board, or a multi-layer board.

19. The circuit board of claim 1, wherein the circuit board is processed by wave soldering, reflow soldering, or manual soldering.

20. An electrical connection device, comprising the circuit board of claim 1, a power cord, a detection-protection apparatus arranged at the circuit board and connected to the power cord, and a housing enclosing the circuit board, wherein the housing is arranged with conductive pins for accessing a power supply.
